(19) United States
(12) Patent Application Publication
(10) Pub. No.: US 2004/0174596 A1
(43) Pub. Date: Sep. 9, 2004

(54) Polarization optical device and manufacturing method therefor

(75) Inventor: Kazuhiro Umeki, Iwate (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: RICOH OPTICAL INDUSTRIES CO., LTD., Hanamaki-shi (JP)

(21) Appl. No.: 10/792,539

(22) Filed: Mar. 4, 2004

(30) Foreign Application Priority Data
Mar. 5, 2003 (JP) 2003-058061
Jun. 23, 2003 (JP) 2003-178791

(51) Int. Cl. H01L 21/76; G02B 5/30

(52) U.S. Cl. 359/484

(57) ABSTRACT

A polarization optical device is disclosed that includes: an inorganic dielectric substrate transparent with respect to incident light having a flat surface; and an array of strips of conductive elements embedded from the flat surface of the inorganic dielectric substrate to a uniform depth, with an equal width, and with an equal separation in a pitch shorter than the wavelength of the incident light in a manner such that the surfaces of the strips of conductive elements are flush with the surface of the substrate.

### BACKGROUND OF THE INVENTION

1. Field of the Invention

The present invention relates to a product providing an optical function obtained from hyperfine processing performed on a surface of a member for the device, to a manufacturing method therefor, and, in particular, to an inorganic polarization optical device (an optical device which utilizes an electromagnetic wave component in a property of light) having an array of many strips of conductive elements arranged with an equal separation in a pitch shorter than the wavelength of incident light in a surface of an inorganic dielectric substrate, and a manufacturing method therefor.

2. Description of the Related Art

There are two types of polarization optical devices, i.e., those in an ‘organic material product’ type using organic sheet material and those in an ‘inorganic material product’ type in which then metal wires are arranged in the form of an array on an inorganic material substrate.

A polarization optical device in the ‘organic material product’ type is made of an organic high-polymer material having constituents including PVA (polyvinyl alcohol) as the principal component thereof. A method of manufacturing it is as follows: After a PVA film material is impregnated with iodine material or organic dye and they are mixed, the resultant material is spread in an X direction or X-Y directions. Then, the material is bonded by organic film materials such as PVA or so in a sandwiching manner from the top and the bottom thereof. Therefore, such a product is called a ‘dichroic polarizer’. As it is formed from the organic high-polymer material, the allowable working temperature is limited to below 100° C.

A ‘polarization plate’ made of PVA material is inexpensive and is sufficient to function as a polarization plate for a portable liquid crystal device. It is not possible to use it as a polarization plate for a liquid crystal projector for which recent demand has been increasing rapidly, since this product may not have sufficient heat resistance nor sufficient durability. The liquid crystal projector is used for a TV having a large-sized screen, or a display device having a large-sized screen for the purpose of presentation, for example. This device is an optical product in which light from a high brightness lamp is optically condensed into high density light, and then, is applied to a liquid crystal panel perpendicularly. In this product, the temperature around the liquid crystal panel may increase up to 120° C. In order to lower the temperature, usually a cooling fan or such is provided. Further, in this application field, this type of product may have the function thereof degraded when short-wavelength light is applied for a long interval.

In such an application field of the organic material product type of polarization optical device, effective cooling is important, and, for this purpose, some countermeasures have been taken such as \mathring{1} to install a cooling fan, \mathring{2} to employ a black matrix (BM) which absorbs the heat of the panel or to provide a reflective film on the BM panel, \mathring{3} to use a metallic panel frame pair, \mathring{4} to employ a sapphire glass having high heat conductivity (40 times that of glass) as supporting equipment therefor, or such. However, each measure increases the total costs of the apparatus, and thus, fundamentally the problem may not be solved.

The above-mentioned ‘inorganic material product’ type of polarization optical device has been devised for the purpose of solving the above-mentioned problem. As mentioned above, as this type of device, a polarization optical device is known in which thin metal wires are arranged in a form of array on an inorganic material substrate, and thus, on a surface of the inorganic dielectric substrate, the array of many strips of conductive elements arranged with an equal separation in a pitch shorter than the wavelength of incident light is provided. In this regard, see Japanese Laid-open Patent Application No. 2003-502708, as well as U.S. Pat. Nos. 6,208,463, 6,122,103, 6,243,199 and 5,458,084.

FIG. 1 shows a general configuration of such a type of polarization optical device. This device includes, as shown, on a dielectric substrate 20, an array of many strips of conductive elements 22 each having a width W are arranged in parallel with a pitch P shorter than the wavelength of incident light. When the incident light 24 is applied to this polarization optical device with an angle θ from the normal, with an incident plane perpendicular to the length direction of the conductive elements 22, the polarization optical device has a function of providing reflected light 26 having a polarization component of the incident light 24 having a polarization vector perpendicular to the incident plane and transmitted light 28 having a polarization component of the same having a polarization vector parallel to the incident plane.

This inorganic material product type of polarization optical device is manufactured with the use of X-ray exposure and a lift-off method, and aluminum wires are formed as the conductive elements 22 on a glass material.

As a manufacturing method for such a hyperfine structure including the array of conductive elements, the following two types of methods A) and B) have been proposed: A) As disclosed by a journal, ‘Applied Physics’, volume 68, number 6 (1999), pages 633-638, “Fabrication technology of high-efficiency diffractive optical element”, a direct writing method with the use of an electron beam, a laser beam or an ion beam, photolithography and dry etching technology are combined. B) A lecture summary for ‘the 27th Optics Symposium’ (2001), pages 25-36 discloses, as a manufacturing method for a composite functional diffraction device, ‘an effective refractive index method’ of controlling a phase modulation amount in a light wave with the use of a combination of elements having configurations characterized by a filling factor of a fixed relief depth (in a binary level).

### SUMMARY OF THE INVENTION

In the above-mentioned ‘inorganic material product’ type of polarization optical device in the related art, as the aluminum conductive elements are formed on the surface of a glass substrate, a problem may occur in terms of durability of the product since adhesiveness between the glass substrate material and the aluminum conductive elements may not be sufficient and thus, they may be easily separated from each other.

Furthermore, since fine unevenness occurs on the surface from the hyperfine structure including the array of conductive elements, dirt/dust or such may be put into the depressions thereof if the device is directly handled by hands, and the dirt/dust may not be removed therefrom easily. Thus, trouble may occur from handling it.

Therefore, a first object of the present invention is to provide a polarization optical device in the ‘inorganic material product’ type having sufficient durability and also, providing easiness in handling thereof.

A method for forming a hyperfine three-dimensional structure such as that to which the present invention is directed, having an L/S (line and space) shorter than an optical wavelength applied thereto is next discussed. For example, in particular, the above-mentioned method A) from among the methods A) and B) is discussed. Although a manufacturing research report for a diffraction optical device exists, this report includes an example of the device having a taper structure in a cross-sectional view, and also, the pitch is merely 0.7 times the wavelength applied (0.7λ). Furthermore, the following problems may occur:

(i) When employing a mask exposure method with the use of a laser beam, an ion beam or an X-ray beam, a L (line) width which can be formed therefrom has a limit (i.e., it is not possible to form L which is shorter than the wavelength of light applied for the exposure). Accordingly, it is not possible to form a sufficiently small hyperfine structure.

(ii) Problems such as those \mathring{1} through \mathring{6} mentioned below may occur when the direct writing method with the use of an electron beam is applied:

\mathring{1} A very long time is taken for performing writing for a wide area (10 through 15 hours are needed for a square of 500 μm×500 μm, for example).

\mathring{2} The writing area is fixed as 500 μm×500 μm, and thus it is necessary to repeat the effective area thereof several times to achieve a wider area.

\mathring{3} In this case of repeating the effective area to achieve a wider area as mentioned above, although, on the order of 15 nm of accuracy a is obtained at the border between adjacent areas obtained from the repetition, this accuracy at the border between adjacent areas may be degraded when the number of times of the repetitions increases for the following reasons a) through d):

a) As the time interval for the writing increases, a (beam generation) filament current amount fluctuates during the writing;

b) As the time interval taken for the writing increases, writing positional accuracy decreases accordingly;

c) The filament itself may be degraded in its quality; and

d) The writing accuracy may not be sufficiently high according to the performance of the writing apparatus itself (depending on the apparatus design or so).

\mathring{4} The repeatability in the writing may not be sufficiently high.

\mathring{5} A defect may be likely to occur during the writing.

\mathring{6} As a device which has a control performance with a high precision is needed for achieving the precise writing result, the writing apparatus may become expensive in total (for example, 1 billion through 1.5 billion yen per unit).

Accordingly, it may not be advantageous to apply the direct writing method with the use of an electron beam as a manufacturing method for mass production requiring a stable and inexpensive product supply. In fact, there has been no case where this method has been put into-practical use.

Thus, a second object of the present invention is to provide a method for manufacturing a polarization optical device in the ‘inorganic material product’ type having a three-dimensional surface structure (hyperfine structure including an array of conductive elements) with high accuracy through a simplified production process for supplying products inexpensively with high repeatability.

According to the present invention, there are provided an inorganic dielectric substrate transparent with respect to incident light having a flat surface; and at least one array comprising a plurality of strips of conductive elements embedded in the flat surface of the inorganic dielectric substrate with a uniform depth, with an equal width, and with an equal separation at a pitch shorter than the wavelength of the incident light in a manner such that the surfaces of the strips of conductive elements are flush with the surface of the substrate.

In this configuration, since the conductive elements are embedded in the substrate, sufficient heat resistance is provided. Also, since the conductive elements are thereby prevented from easily being separated from the substrate, sufficient durability is also provided. Furthermore, since the surface including the conducive elements provided therein is flat without unevenness, even if dirt/dust adheres thereto as a result of the device being handled directly by hands, the dirt/dust can be easily removed therefrom. Thus, handling of the device becomes easier.

A manufacturing method for manufacturing this polarization optical device according to the present invention includes the following steps, in the stated order:

a) manufacturing a metal mold having a fine structure comprising an array of projections arranged with an equal separation shorter than that of the wavelength of incident light with an equal height and an equal width on a flat surface;

b) pressing a product substrate onto the metal mold via a hardenable resin and transferring the surface shape of the metal mold into the resin on the product substrate;

c) hardening the resin;

d) removing the metal mold from the resin in a state in which the resin is bonded with the product substrate;

e) transferring the shape once transferred into the resin in the step b) further into the product substrate according to a dry etching method; and

f) filling in depressions formed in the surface of the product substrate in the step e) with metal.

This method generally includes the following two steps of: \mathring{1} forming a hyperfine three-dimensional structure of L/S (lines and spaces) on a desired substrate; and \mathring{2} filling in the groove parts of this three-dimensional structure with a metal film.

According to the present invention, the hyperfine three-dimensional structure of L/S (for an array of conductive elements) is transferred into resin with the use of a metal mold, and the thus-transferred structure is then again transferred into a product substrate. Even though it may be necessary to use an expensive writing device for manufacturing the metal mold so as to achieve high accuracy there and also a considerable time may be needed for the writing process, it is not necessary to perform a direct writing process for manufacturing each product in mass production once the metal mold is thus manufactured at high accuracy, since the manufactured metal mold can be used for producing each particular product repetitively. Accordingly, the manufacturing process is simplified, and also, polarization optical devices can be produced with high repeatability at low cost.

According to a second aspect of the present invention, an inorganic dielectric substrate transparent with respect to incident light having a flat surface; an array comprising a plurality of strips of conductive elements embedded in the flat surface of the inorganic dielectric substrate with a uniform depth, with an equal width, and with an equal separation at a pitch shorter than the wavelength of the incident light in a manner such that the surfaces of the array of the strips of conductive elements are flush with the surface of the substrate itself; and a protective layer transparent with respect to the incident light having a flat surface provided on the surface of the inorganic dielectric substrate including the strips of conductor elements, are provided.

In this configuration, since the conductive elements are covered by the protective layer, sufficient heat resistance is provided. Also, since the conductive elements can be effectively prevented from being separated, by the protective layer, sufficiently high durability is also provided. Furthermore, since the surface of the protective layer is flat without unevenness, even if dirt/dust adheres thereto as a result of the device being directly handled by hands, the dirt/dust can be easily removed. Thus, easier handling is provided.

A manufacturing method for manufacturing this polarization optical device in the second aspect of the present invention includes the following steps, in the stated order:

a) manufacturing a metal mold having a fine shape comprising an array of depressions arranged with an equal separation shorter than that of incident light with an equal height and an equal width on a flat surface;

b) forming a metal layer on a surface of a product substrate;

c) pressing the metal layer of the product substrate onto the metal mold via a hardenable resin and transferring the surface shape of the metal mold-into the resin on the metal layer;

d) hardening the resin;

e) removing the metal mold from the resin in a state in which the resin is bonded with the metal layer;

f) further transferring the shape once transferred into the resin in the step c) into the metal layer according to a dry etching method so as to form an array of strips of conductive elements;

g) forming a protective layer on the product substrate including the array of strips of conductive elements; and

h) flattening a surface of the protective layer.

This method generally includes the following four steps of: \mathring{1} forming a metal layer on a product substrate; \mathring{2} forming a hyperfine three-dimensional structure of L/S (lines and spaces) on the product substrate; \mathring{3} filling in the groove parts (zones left among respective elements of the three-dimensional structure) of this three-dimensional structure with a protective layer; and \mathring{4} flattening the surface of the thus-formed protective layer.

According to the above-mentioned second aspect of the present invention, the hyperfine three-dimensional structure of L/S is transferred into resin with the use of a metal mold, and the thus-transferred structure in resin is then again transferred into the metal layer formed on the product substrate. Even though it may be necessary to use an expensive writing device for manufacturing the metal mold so as to achieve high accuracy there and also a considerable time may be needed for the writing process, it is not necessary to perform a direct writing process for manufacturing each product in mass production once the metal mold is thus manufactured at high accuracy, since once manufactured metal mold can be used for this purpose repetitively. Accordingly, the manufacture process is simplified, and also, polarization optical devices can be produced with high repeatability at low cost.

Other objects and further features of the present invention will become more apparent from the following detailed description when read in conjunction with the accompanying drawings.

### BRIEF DESCRIPTION OF THE DRAWINGS

FIG. 1 shows a general perspective view of a polarization optical device in the related art;

FIGS. 2A and 2B illustrate a polarization optical device in a first embodiment of the present invention (FIG. 2A shows a general plan view while FIG. 2B shows a cross-sectional view taken from cutting a part thereof including an array of conductive elements along a vertical direction);

FIGS. 3A through 3J illustrate process cross-sectional views of a manufacturing method according to the first embodiment of the present invention;

FIGS. 4A and 4B illustrate a polarization optical device in a second embodiment of the present invention (FIG. 4A shows a general plan view while FIG. 4B shows a cross-sectional view taken from cutting a part thereof including an array of conductive elements along a vertical direction);

FIGS. 5A through 5I illustrate process cross-sectional views of a manufacturing method according to the second embodiment of the present invention;

FIGS. 6A and 6B illustrate a polarization optical device in a third embodiment of the present invention (FIG. 6A shows a general plan view while FIG. 6B shows a cross-sectional view taken from cutting a part thereof including an array of conductive elements along a vertical direction);

FIGS. 7A through 7E illustrate process cross-sectional views of a manufacturing method according to the third embodiment of the present invention;

FIGS. 8A and 8B illustrate a polarization optical device in a fourth embodiment of the present invention (FIG. 8A shows a general plan view while FIG. 8B shows a cross-sectional view taken from cutting a part thereof including an array of conductive elements along a vertical direction);

FIGS. 9A through 9D illustrate process cross-sectional views of a manufacturing method according to the fourth embodiment of the present invention; and

FIG. 10 shows a general plan view of a polarization optical device in a fifth embodiment of the present invention.

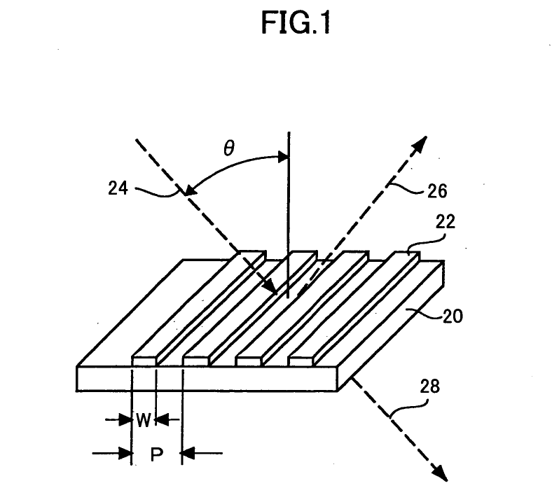

### DETAILED DESCRIPTION OF THE PREFERRED EMBODIMENTS

According to the present invention, it is preferable that a reflection preventing film be formed on a surface opposite to the surface of a product substrate in which an array of strips of conductive elements is embedded. Thereby, it is possible to create an inexpensive polarization device having good adhesiveness with respect to a hyperfine structure, having high heat resistance, high durability and high optical efficiency.

It is also preferable that, in a zone other than the zone in which the array of strips of conductive elements is formed, a conductive layer which is connected to the strip conductive elements be embedded. In this case, when the surface of the polarization optical device generates heat from the array of strips of conductive elements, it is easy to cause the heat to radiate. This effect is further increased when a heat radiation plate is provided in contact with the conductive layer.

Further, it is preferable that, in the manufacturing method mentioned above, before the product substrate is pressed onto the surface of the metal mold via the resin, predetermined mold releasing processing be performed on the surface of the metal mold. An example of the mold releasing processing performed on the surface of the metal mold is to form a metal thin film on the surface of the metal mold. By this mold releasing processing, shape transfer performance of the metal mold is sharply improved, thus precise shape transfer can be achieved; and also, the service life of the metal mold is sharply increased since removal of the metal mold from each product can be made easier.

Furthermore, it is preferable to, as the mold releasing processing, perform further surface treatment on the above-mentioned metal layer with a layer of a fine structure including fluororesin.

It is also preferable that, before the product substrate is pressed onto the metal mold on which the above-mentioned mold releasing processing is performed previously, via the resin, a primer surface treatment be performed so as to improve the adhesiveness between the resin and the surface of the product substrate. Thereby, during a mold releasing process, separation occurs selectively from the metal mold, and thus, a problematic situation in which a part of the resin remains on the metal mold after the separation can be effectively avoided. As a result, the shape transfer performance in the subsequent process can be improved.

As the resin used for transferring the reversed shape of the surface structure of the metal mold, ultraviolet curing resin, thermo-set resin or such may be applied.

The following advantages may be obtained when ultraviolet curing resin is applied as mentioned above: \mathring{1} Hardening occurs at ordinary temperature. \mathring{2} Since coating thereof can be made in a liquid state, sufficient flowability is provided, and also, it is possible to prevent bubble generation therein or so forth. \mathring{3} Since hardening is achieved with a uniform application of ultraviolet rays, it is possible to achieve uniform hardening. \mathring{4} It is possible to achieve hardening within a short time. As a result, it becomes possible to easily achieve precise transfer of the surface structure from the metal mold.

Also in the case where the thermo-set resin is applied as the resin of the shape transfer medium mentioned above, it is possible to precisely transfer the surface structure of the metal mold similarly to the case of using the ultraviolet curing resin as long as uniform hardening is achieved. As the thermo-set resin, resin commonly used for manufacturing a plastic eyeglass lens or a contact lens may be applied.

In case of applying the ultraviolet curing resin as the resin used for transferring the reversed structure of the surface structure from the metal mold, the following method for hardening the ultraviolet curing resin is preferably applied: An ultraviolet ray transmission material is selected as the material of at least one of the metal mold and the product substrate, ultraviolet rays are applied through any one or both of the metal mold and the product substrate made of ultraviolet ray transmission material during a process of hardening the ultraviolet curing resin, and thus, the ultraviolet curing resin is hardened uniformly. By uniformly hardening the ultraviolet curing resin, the shape transfer performance from the metal mold is sharply improved, and thus, a precise shape transfer can be achieved.

A preferable method of hardening the resin used for transferring the reversed structure of the surface structure from the metal mold when the thermo-set resin is applied is next described. In a state in which the metal mold and the product substrate are appropriately positioned with respect to one another, they are fixed, and a resin injection hole is specially provided. During a process of hardening the thermo-set resin, while the above-mentioned combination of the metal mold and the product substrate is gradually heated, thermal hardening is performed in a manner such that heat conduction occurs uniformly throughout the entire metal mold.

Generally speaking, resin shrinks when it is hardened. Therefore, it is preferable that, the amount of shrinkage should be previously calculated, then, in a process of transferring a desired structure into a metal mold host material through dry etching of photosensitive material, the work should be performed to include a correction such that the structure in the metal mold host material is deeper so as to accommodate the above-mentioned previously calculated of shrinkage. Furthermore, it is also preferable that a control be made quantitatively such that the flat surface part of the metal mold and the flat surface part of the product substrate are parallel with respect to one another and the gap therebetween becomes minimum. Thereby, it becomes possible to properly correct the shrinkage amount.

A preferable method for forming the fine structure in the metal mold includes the following steps g), h) and i), in the stated order:

g) coating photosensitive material (resist) onto the surface of a host material for the metal mold in which the fine structure will be formed;

h) writing a desired shape on the photosensitive material with an electron beam (EB), developing it and thus forming the desired shape in the photosensitive material; and

i) transferring the shape in the photosensitive material to the host material for the metal mold according to a dry etching method.

By employing the way of writing the desired shape with the use of the electron beam, it is possible to produce the desired shape at high accuracy with only a single process.

Furthermore, by employing the dry etching method for transferring the shape of the photosensitive material to the metal mold host material, it is possible to transfer the structure from the resist, which is soft material, to the hard metal mold material.

In this case, the host material for the metal mold should be one allowing the dry etching process to be performed thereon. As this material, one selected from silicon material, semiconductor material, metal material, glass material, ceramic material, plastic material and hard rubber material may be applied.

Generally speaking, a metal mold host material is a flat substrate, and then, from a flat surface thereof, a fine structure is formed.

In a case of applying a photosensitive material prepared for writing thereto with the use of an electron beam for forming a photosensitive material pattern on the metal mold host material for the metal mold, any one of a positive type resist and a negative type resist may be used as the photosensitive material for writing with an electron beam. However, in a case of coating with the positive type resist and performing writing processing according to an electron beam writing method in-the method for producing such a fine structure, advantages will be provided such as the repeatability in writing is superior, and also, control of handling leakage of the electron beam is easier and thus the control of the writing process is easier.

When producing the metal mold, during a process in which the structure of the photosensitive material is transferred to the metal mold host material according to a dry etching method, it is preferable to change the selectivity stepwise or continuously so as to transfer the desired structure in a manner in which the transfer occurs more in the depth direction (so that the aspect ratio becomes large). By stepwise or continuously changing the selectivity, it becomes possible to obtain the desired structure in the metal mold more deeply. There, the term ‘metal mold’ means a thing which has a basic structure, and thus, means ‘an original which has a basic structure to be transferred’. Although no further details are described here, it is also possible that, based on the above-mentioned ‘metal mold’ (mother mold), another metal mold (sister mold) is produced (although the structure is reversed) according to an electroforming method, and the thus-obtained sister mold may be used as the metal mold for transferring the hyperfine structure for an embodiment of the present invention. In this case, there is no special limitation in the material, and a metal, an alloy material or such may be applied as long as plating can be made on the material.

In a case of transferring the structure once transferred to the resin from the metal mold then to the product substrate according to a dry etching method, it is preferable to change stepwise or continuously the etching selectivity between the resin and the product substrate in the dry etching process for the purpose of forming a desired shape in the product substrate. By adjustment of the selectivity, it is possible to correct the shape in the depth direction, and thus, it becomes possible to transfer the desired deep shape. Furthermore, it is possible to achieve flatness of the surface of the substrate by terminating the etching process (for transferring the hyperfine structure) on the way so as to leave a small amount of the resin layer on the surface of the substrate, and then, removing the thus left resin part together with a seed layer.

With regard to a method of filling in grove parts in such a three-dimensional hyperfine structure formed in the product substrate with the metal film, W or Cu has been proposed as a material used for filling in through holes of 0.1 μm (=100 nm) in the semiconductor integrated circuit manufacturing field. However, in the polarization optical device according to the present invention, since various requirements should be satisfied, i.e., (i) the line width of each line may become further reduced to less than 100 nm, (ii) Al (aluminum) is preferable as a material which has a high reflectivity, (iii) positive filling-in performance is required, (iv) bubbles should not occur in the material thus embedded, and so forth, there may occur a problem if the conventional method of simply forming a metal film is applied as it is.

In a preferable method according to the present invention, an Al-CVD (aluminum CVD) method is applied for forming a metal film over the hyperfine structure already produced with high throwing power, as a method of employing aluminum as a preferable metal to be used for filling in the groove parts in the hyperfine structure.

According to the Al-CVD method, first, a seed layer is formed using a sputtering method in an ultra-high vacuum condition, from which seed layer an aluminum film grows in a reduction reaction. The seed layer is made of material of Ti or TiN. By this method, a film of TiN or Ti is formed as the seed layer in the hyperfine holes occurring in the target substrate.

As the necessity arises, it is possible that the etching process for transferring the hyperfine structure will be terminated on the way in a state in which a little of the resin layer is left on the surface of the substrate as mentioned above, and the process of removing the resin layer is performed during this Al-CVD process.

Then, a special gas prepared for the Al-CVD process is heated and evaporated, and then, is introduced into a special CVD film forming chamber. In the chamber, since the surface of the product substrate is heated to a temperature so high that a reduction CVD reaction may positively occur, a metal aluminum film grows (through deposition of the material) on the surface of the seed layer on the surface of the substrate.

On the surface in which holes (grooves) in the hyperfine structure are thus completely filled in, the film is produced that slightly over fills the holes, i.e., the film thickness thus obtained is greater than the depth of these holes. Accordingly, the entire surface of the glass substrate is completely covered by the aluminum. However, since the film may not be formed uniformly throughout the entire surface of the substrate during the growth of the aluminum film, the surface morphology may be roughened on the order of several nanometers through several tens of nanometers in a microscopic view. In order to eliminate this roughness, it is preferable to perform a reflow process. This process is a heating reflow process in which, after the metal CVD film formation process, the product substrate is heated to a temperature higher than that at which the metal melts in the vacuum chamber without exposing it to the air, and thus, the surface of the metal film is flattened accordingly. By performing this heating reflow process, the aluminum on the surface of the substrate is flattened by the surface tension and the gravity in directions parallel to the surface of the substrate i.e., perpendicular to the gravity direction.

After that, in order to cause the product substrate to have a desired optical function as the polarization optical device, the surface is ground or polished while controlling the grinding/polishing amount at high accuracy according to a CMP (chemical mechanical polish) process, or etching is performed on the surface in a dry etching apparatus, i.e., so-called etch back is performed so that the metal aluminum film on the surface of the substrate is removed, up to the product substrate surface on which the above-mentioned hyperfine structure is formed, so as to expose the transparent glassy transmission lines on the substrate surface.

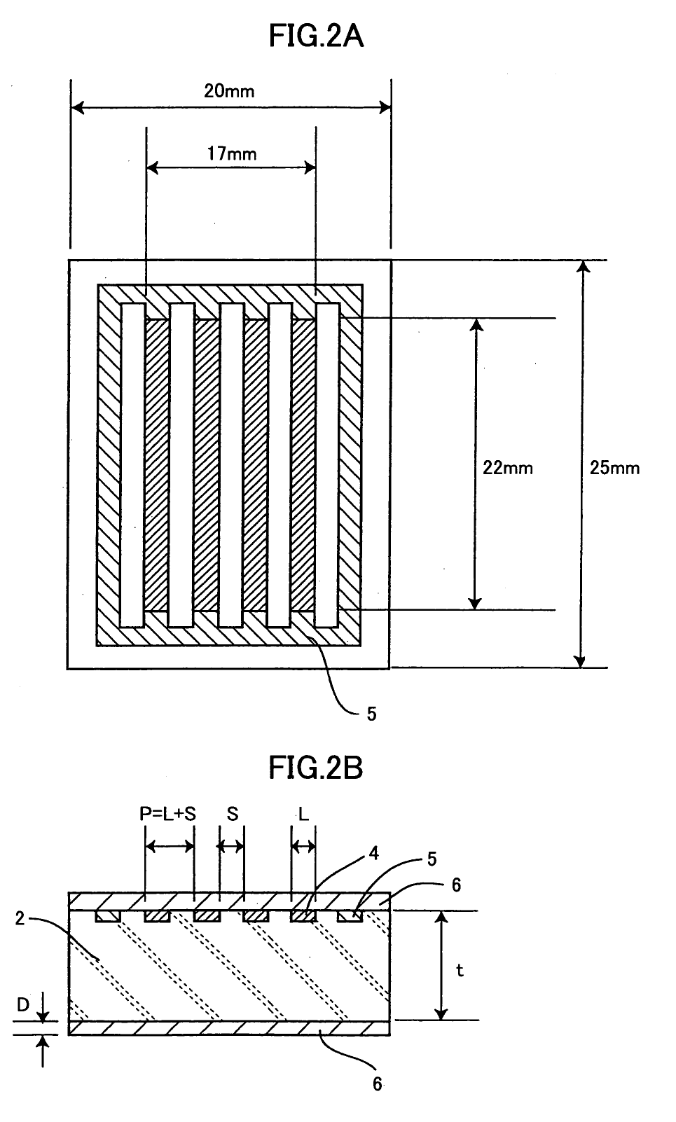

Actual embodiments of the present invention are next described. In a first embodiment, a polarization optical device as shown in FIGS. 2A and 2B was produced. This polarization optical device has a configuration in which conductive elements 4 are arranged in a form of an array produced from filling in with aluminum a groove structure with a land and space L/S of 35 nm/35 nm, a pitch P of 70 nm and a depth D of 110 nm formed on a surface of a synthetic quartz substrate 2 having a thickness of 1.0 mm. The substrate 2 has a size of 25 mm×20 mm as shown, and an effective area of the device is 22 mm×17 mm. In the array, the conductive elements 4 with the above-mentioned L/S are arranged in a regular pattern parallel to the longitudinal direction of the substrate 2. ‘L’ (line) denotes a part which is filled in with the aluminum film, while ‘S’ (space) denotes a part in which the quartz remains. ‘P’ denotes the pitch of L+S. In the figures, the polarization optical device is shown in a manner in which only the four lines (L) of conductive elements 4 are illustrated in a magnified manner for the purpose of simplification.

In an area having a width of several millimeters surrounding the array of conductive elements 4 a belt-like zone exists in which there is no conductive element 4. In this area, a conductive layer 5 connected to the conductive elements 4 is embedded. The conductive layer 5 is an aluminum film as in the conductive elements 4, and can be produced at the same time at which the conductive elements 4 are formed.

On both obverse and reverse sides of the polarization optical device, reflection preventing films 6 are formed. Each of the reflection preventing films 6 is a film having five layers including, for example, an MgF₂ film(s), a SiO₂ film(s) and a TiO₂ film(s). The range of wavelengths for which each of these reflection preventing films 6 has a reflection preventing function is between 380 and 700 nm, and the transmittance there is more than 99% when the transmittance of the quartz substrate 2 is assumed as 100%.

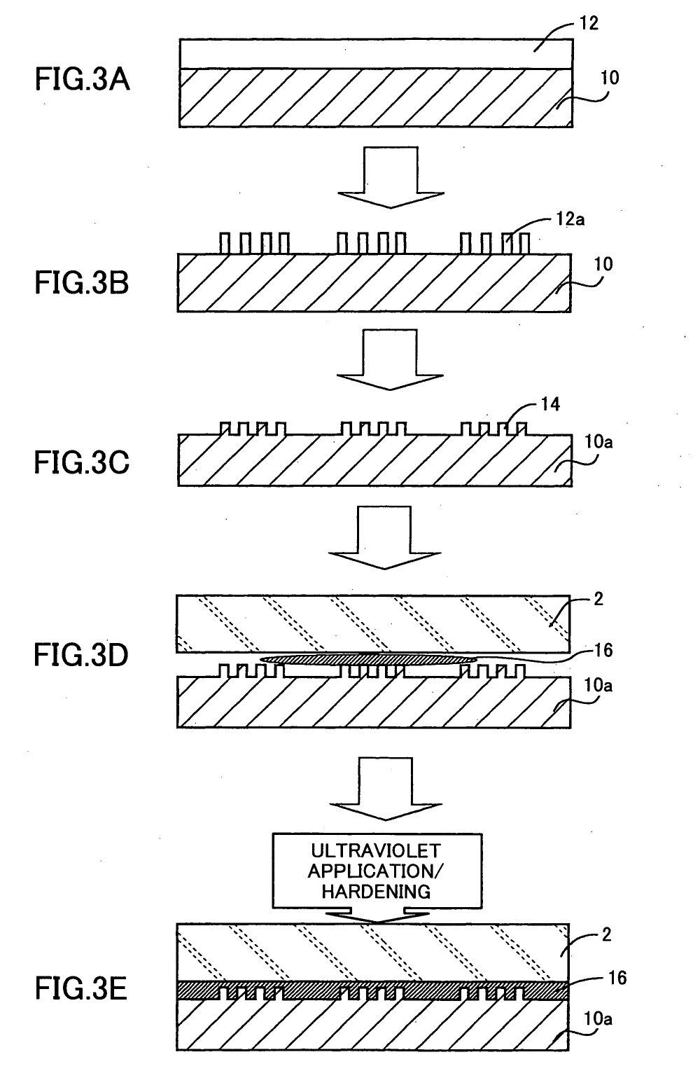

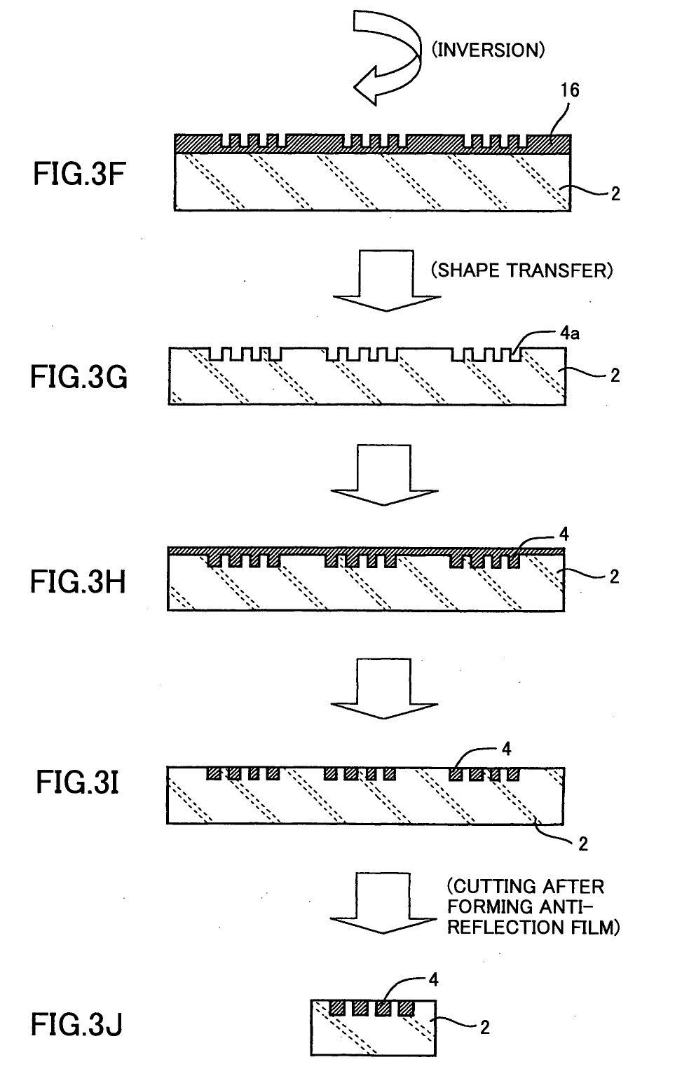

FIGS. 3A through 3J illustrate a manufacturing procedure for this polarization optical device according to the first embodiment of the present invention.

In a step of resist coating and writing shown in FIG. 3A, photosensitive material prepared for electron beam writing is applied to form a coat on a metal mold host material, and then writing is performed with the use of an electron beam.

Specifically, as the metal mold host material 10, a silicon substrate having a diameter of 6 inches and a thickness of 1.0 mm was used. On the surface of this metal mold host material 10, photosensitive material (resist) 12 (ZEP-520 made by Zeon corporation) prepared for an electron beam writing process was applied with the use of a spinner for five seconds at 500 rpm and then, for 30 seconds at 4000 rpm. Then, after pre-baking was performed for five minutes at 90° C., rapid cooling was performed. At this time, the film thickness of the resist obtained was 0.14 μm.

Then, in order to obtain a reversed structure (projections and depressions are reversed) of the structure shown in FIGS. 2A and 2B, data of area separation, paths, a beam diameter, a dose amount, a writing time and so forth in tracing with an EB application beam was previously input to a personal computer with the use of special software. In this embodiment, the entire area for writing was divided into squire areas each having a size of 500 μm×500 μm, a writing program was produced therefor, and finally, writing for the entire area of 22 mm×17 mm was achieved by repeating a writing process for the above-mentioned divided areas, while appropriately connecting these divided areas together. In this embodiment, since the structure in the final product and the writing structure have a revere relationship therebetween, the software program for the reversed structure should be produced accordingly.

The metal mold host material 10 having the resist 12 formed as a coat thereon was set in an electron beam writing apparatus, and then, the air in the apparatus was evacuated to a predetermined vacuum. After that, the special data input as mentioned above was transferred to a control unit of this writing apparatus, and then, a writing process with the use of an electron beam was started in this apparatus. In this embodiment, a system was employed in which writing was performed while an X-Y stage on which the metal mold host material was placed was moved. The writing process required 48 hours.

Then, the process of developing and rinsing shown in FIG. 3B was performed. FIG. 3B illustrates a cross-sectional view of a pattern after a developing process was performed.

After the above-mentioned writing process, with the use of developer (ZEP-520 developer), developing was performed for three minutes at 25° C. Then, rinsing was performed, and immediately after that, drying was performed with the use of a nitrogen blower while rotation was performed by the spinner. Furthermore, post-baking was performed for five minutes at 120° C. As a result, the photosensitive material (resist) 12 was shaped into a pattern 12a for the hyperfine structure.

Then, the process of producing the metal mold by dry etching with the use of the photosensitive material 12 thus shaped into the pattern 12a as a mask, and then, removing the photosensitive material as the necessity arose, was performed as shown in FIG. 3C.

The pattern 12a of the resist formed through the writing process was transferred to the metal mold host material 10 according to a dry etching method. At this time, in the dry etching process, etching was performed with the use of a TCP (induction coupled plasma) etching apparatus, while gas of CF₄ was introduced in 20 sccm, with a substrate bias voltage of 500 V, with top electrode power of 1250 W and vacuum of 1.0×10⁻³ Torr (i.e., 1.0 mTorr) for 0.5 minutes. At this time, the etching rate was 0.18 μm/minute. The etching was finished in a state of a small (on the order of 0.01 μm) under-etching. That is, a small amount of the resist remained on the surface. The selectivity (the etching rate for the metal mold host material/the etching rate for the resist) in the etching was 1.0, and the height of the structure 14 in the metal mold 10a resulting from the etching was 0.12 μm (120 nm). The surface roughness Ra of the surface was less than 0.002 μm, and thus, was sufficiently low. This height of the structure 14 was set in expectation of being selectivity applied in a subsequent process and resin shrinkage (7%). At this time, the metal mold structure 14 had the same pitch and only the height was set to be reduced 0.9 of the height, with respect to the state obtained after undergoing the writing process.

In order to perform mold releasing processing on the surface of the metal mold 10a, surface treatment was performed with a triazin thiol organic compound having a fluorine functional group. This process was performed according to a method called the organic galvanizing method. Specifically, electrolytic polymerization processing (organic galvanizing) was performed in a solution in which a fluorinated SFTT (super fine triazin thiol) was dissolved in solvent, and thus, a fluorine organic thin film was formed on the surface of the metal mold. The above-mentioned fluorinated SFTT is one which is obtained from fluorinating a side chain of triazin thiol, which is one of organic sulfur compounds. Since, as to the number ‘n’ of the fluorine molecules, n=7 provided the most water repellent effect (mold releasing effect), this condition was applied, and then, the film was formed for 100 Å.

Then, the process of FIG. 3D was performed in which resin was formed as a coat onto the metal mold pattern, and then, a product substrate was pressed thereto from the top.

The metal mold undergoing the mold releasing process as mentioned above was set first, and then, on the top thereof, acrylic resin (GRANDIC RC-8720 made by Danippon Ink and Chemicals, Incorporated) as ultraviolet curing resin 16 which is a preferable resin was applied as a coat 1 cc thick. Then, this metal mold 10a was set in a special bonding machine, and then, a flat substrate 2 (synthetic quartz, SUPRASIL-P-20, made by Shi-Etsu Chemical, Co., Ltd.) which was the product substrate which previously had undergone silane coupling processing in a separate process, was pressed thereon slowly with the surface thereof having undergone the silane coupling processing applied to the metal mold 10a as shown in FIG. 3D. At this time, the automatic bonding machine was used by which the lowering speed of the product substrate 2 and the parallelism between the metal mold 10a and the product substrate 2 (so that the gap therebetween becomes less than 50 nm) were controlled so that generation of bubbles in the ultraviolet curing resin 16 was avoided.

Then, the metal mold 10a was slowly pressed up onto the product substrate 2 from the bottom, and a part of the ultraviolet curing resin 16 which was extraneous structure transfer processing was removed.

Then, the process of FIG. 3E in which the ultraviolet curing resin was hardened and was removed, was performed.

In this process, from the reverse side of the product substrate 2, uniform ultraviolet rays of 3000 mJ were applied, and thus, the ultraviolet curing resin 16 was hardened. At this time, the thickness of the ultraviolet curing resin 16 (the distance between the top of the pattern 14 of the metal mold 10a and the product substrate 2) was less than 0.05 μm. Accordingly, the maximum height of the ultraviolet curing resin 16 was less than 0.17 μm (=the pattern depth of 0.12+the above-mentioned distance of less than 0.05).

Then, the process of FIG. 3F was performed in which the metal mold was removed from the product substrate.

Specifically, in order to separate the ultraviolet curing resin 16 from the metal mold 10a in a state in which the ultraviolet curing resin 16 was bonded to the product substrate 2, a jig was used, and, while the metal mold silicon material 10a was slightly deformed to be bent into a convex form, the separation was achieved while maintaining the parallel state therebetween.

When the thus-transferred structure on the resin layer 16 on the surface of the product substrate 2 (see FIG. 3F) was measured, the height of the optical device part was reduced to 0.11 μm (110 nm) from the above-mentioned pattern depth of 0.12 μm. This is because the resin layer 16 shrank while being hardened, and the shrinkage ratio was approximately 8.5%.

The process of FIG. 3G was then performed in which the resin structure was transferred to the product substrate itself according to a dry etching method.

Specifically, the same as the above, the transferred structure in the resin layer 16 on the product substrate 2 was then transferred to the product substrate 2 itself. At this time, in the dry etching process, etching was performed with the use of a TCP (induction coupled plasma) etching apparatus, while gas of CF₄ was introduced at 20 sccm, with a substrate bias voltage of 500 V, with a top electrode power of 1250 W and vacuum of 1.0×10⁻³ Torr (i.e., 1.0 mTorr) for 0.5 minutes. At this time, the etching rate was 0.10 μm/minute. The etching was finished in a state of a slight (on the order of 0.04 μm) of under etching. That is, a small amount of the resist remained on the surface. The selectivity (the etching rate for the product substrate/the etching rate for the resist layer) in the etching was 1.0, and the height of the structure on the product substrate 2 resulting from the etching was 0.11 μm (110 nm). The surface roughness Ra on the surface was less than 0.002 μm, and thus, was sufficiently low.

The structure resulting from the etching was measured with the use of a measuring SEM apparatus. Specifically, the L/S widths and step heights were measured. In this intermediate process, as the optical device structure thus obtained, a groove structure 4a shown in FIG. 3G in which L/S=35/35 nm, P=70 nm and the depth D=110 nm was produced on the synthetic quartz surface of the product substrate 2.

The process of FIG. 3H was then performed in which, according to an Al-CVD method (\mathring{1} Ti or TiN seed layer+\mathring{2} Al-CVD), the grooves were filled in.

This process was performed in a vacuum apparatus having plural vacuum chambers and using an integration type reaction vessel having a conveyance system at the center.

In the process, a common sputtering apparatus was used, and a TiN film was formed on the order of 8 nm on the surface of the product substrate 2 in which the patter was formed.

Then, as the necessity arose, inverse sputtering was performed for 0.5 minutes in Ar gas for the purpose of surface activation in another chamber. In this process, the surface of the TiN film was activated.

Then, with heating the substrate at 125° C., under a condition of film forming pressure of 47 Pa while MPA (1-methyl pyrrolidine alane) gas was flowed at 10 SCCM for 1 minute, 0.12 μm of Al-CVD film was formed. There, through decomposition reaction, the above-mentioned MPA gas was decomposed into pyrrolidine gas and alane gas including aluminum, and then, from the alane gas, aluminum was deposited onto the surface of the substrate.

At this time, although the grooves were completely filled in, the surface roughness of the aluminum was somewhat large. Therefore, a reflow process was performed for five minutes at 350° C., so as to improve flatness, uniformity, denseness and adhesiveness on the aluminum surface. The film thickness (from the surface of the quartz substrate) resulting therefrom was 10 nm. The surface roughness Ra of the aluminum after undergoing the processing was less than 3 nm, and thus, was sufficiently low.

Then, the process of FIG. 3I was formed in which the metal Al (aluminum) film formed over the quartz surface was removed by an etch back method until the quartz of the product substrate was exposed on the surface thereof.

Specifically, the aluminum film thus formed and having undergone the reflow process was etched out by the etch back (dry etching) method up to the quartz substrate surface of the product substrate. At this time, in this dry etching process, etching was performed with the use of a TCP (induction coupled plasma) etching apparatus, while CF₄ gas at 7 sccm, Ar gas at 10 sccm and BCl₃ gas at 3 sccm were introduced, with a substrate bias voltage of 300 V, with a top electrode power of 1250 W, a substrate temperature of 20° C. and vacuum of 1.0×10⁻³ Torr (i.e., 1.0 mTorr) for 0.5 minutes. At this time, the etching rate was 20 μm/minute (10 nm/0.5 minutes) for the aluminum film and the TiN film. Since etching stop was performed with the use of an end point detector, the etching was terminated in a condition of just etched to the quartz substrate surface. In other words, it was the state in which the aluminum and quartz were exposed on the surface as shown in FIG. 3I. The surface roughness was such that Ra=0.002 μm and thus, was sufficiently low.

Then, the process of FIG. 3J was performed in which the reflection preventing films (not shown in the figure) were formed on both sides of the quartz substrate 2. Until then, the processes were performed with the entire substrate being intact; next it was cut and separated into particular polarization optical devices for providing actual products by means of a dicing apparatus, as shown in FIG. 3J.

For the thus-obtained particular polarization optical devices, the pattern dimension and the optical performance were measured. Specifically, in the product inspection, in a sampling manner, cross-sectional structure evaluation was performed and dimensional measurement was performed with the use of a measuring SEM apparatus. According to the above-described manufacturing method, the polarization performance with the transmittance of 64%, and the contrast of 683 (λ=450 nm) was obtained according to the designed values.

According to the present invention described above, a polarization optical device having sufficiently high heat resistance and superior durability is obtained since sufficient adhesiveness of the conductive elements with respect to the substrate is provided. Furthermore, since the surface of the device is flat without unevenness, even if dust/dirt adheres to the,surface due to direct handling by hands, the dirt/dust adhering thereto can be easily removed. Thus, easy handling of the device product is provided.

Furthermore, in a manufacturing method for a polarization optical device according to the present invention, the fine structure including the array of strips of conductive elements (three-dimensional surface structure with high accuracy) can be provided at high accuracy even in a mass production manner. There, the production process can be simplified, repeatability can be improved, an easy manufacturing process can be achieved and also, cost reduction can be achieved.

The above-mentioned second aspect of the present invention is next described. In the second aspect of the present invention, it is preferable to provide an undercoat layer having adhesiveness with respect to the above-mentioned inorganic dielectric substrate and the strips of conductive elements.

In the manufacturing method according to the second aspect of the present invention, it is preferable that, in the step b) mentioned above, the undercoat layer having adhesiveness with respect to the above-mentioned product substrate and the metal layer be formed on the surface of the product substrate, and the above-mentioned metal layer be formed thereon.

Thereby, it is possible to improve the adhesiveness between the substrate and the strips of conductive elements, and thus, to further improve the heat resistance and durability of the device product.

Furthermore, it is preferable that the polarization optical device according to the second aspect of the present invention includes the above-mentioned undercoat layer formed on the entirety of the above-mentioned flat surface of the inorganic dielectric substrate and also having a reflection preventing function, a reflection preventing film formed on the surface of the above-mentioned protective layer, or a reflection preventing film formed on the surface of the above-mentioned inorganic dielectric substrate opposite to the surface on which the above-mentioned protective layer is provided, or both in combination.

Furthermore, in the polarization optical device according to the above-mentioned second aspect of the present invention, it is preferable that, in the above-mentioned step b), the undercoat layer has a reflection preventing function, and, another step of forming a reflection preventing layer on the surface of the protective layer is performed after the step h), another step of forming a reflection preventing layer on the surface of said product substrate opposite to the surface on which said protective layer is performed after the step h), or another step of forming reflection preventing layers on the surface of the protective layer and also on a surface of the product substrate opposite to the surface on which the protective layer is performed after the step h), or these steps are performed in combination.

Thereby, it is possible to provide an inexpensive polarization optical device having high adhesiveness with respect to the hyperfine structure, high heat resistance, high durability and also high optical efficiency.

According to the above-mentioned second aspect of the present invention, a micro lens array may be formed on the surface of the above-mentioned inorganic dielectric substrate opposite to the surface on which the protective layer is provided. Thereby, in comparison to a conventional method of bonding a polarization optical device with a micro lens array member with the use of adhesive agent, a positioning process and an assembly process can be omitted in this case, and thus, it is possible to reduce the manufacturing costs. Furthermore, in this case, since no adhesive agent is needed for bonding a polarization optical device with a micro lens array member, deformation otherwise occurring due to a difference in thermal expansion coefficients between the adhesive agent and the substrate can be avoided.

According to the above-mentioned second aspect of the present invention, in a zone on the above-mentioned undercoat layer other than a zone in which the strip conductive element array (array of strips of conductive elements) is formed, a conductive layer which is connected to the strip conductive elements is embedded. In this case, when the surface of the polarization optical device generates heat at the strip conductive element array, it is easy to cause the heat to radiate therethrough. This effect is further increased when a heat radiation plate is made to be in contact with this conductive layer.

Further, it is preferable that, in the manufacturing method mentioned above according to the second aspect of the present invention, before the product substrate is pressed onto the surface of the metal mold via the resin in the step b), predetermined mold releasing processing be performed on the surface of the metal mold. An example of the mold releasing processing performed on the surface of the metal mold is to form a metal thin film on the surface of the metal mold. By this mold releasing processing, the shape transfer (or structure transfer) performance of the metal mold is sharply improved, thus precise shape transfer can be achieved, and also, the service life of the metal mold is sharply increased since removal of the metal mold from each product is made easier.

Furthermore, it is preferable to, as the mold releasing processing, perform further surface treatment on the above-mentioned metal layer with a layer of a fine structure including fluororesin.

It is also preferable that, when the product substrate is pressed via the resin onto the metal mold on which the above-mentioned mold releasing processing is performed previously, primer surface treatment be performed so as to improve adhesiveness between the resin and the surface of the product substrate. Thereby, during a mold releasing process, separation occurs selectively from the metal mold, and thus, a problematic situation in which a part of the resin remains on the metal mold after the separation can be effectively avoided. As a result, the shape transfer performance in the subsequent process can be improved.

As the resin used for transferring the reversed shape of the surface structure of the metal mold, ultraviolet curing resin, thermo-set resin or so may be applied.

The following advantages may be obtained when ultraviolet curing resin is applied as mentioned above: \mathring{1} Hardening occurs at ordinary temperature. \mathring{2} Since a coating thereof can be made in a liquid state, sufficient flowability is provided, and also, it is possible to prevent bubble generation. \mathring{3} Since hardening is achieved with a uniform application of ultraviolet rays, it is possible to achieve uniform hardening. \mathring{4} It is possible to achieve hardening within a short time. As a result, it becomes possible to easily achieve precise transfer of the surface structure from the metal mold.

Also in the case where the thermo-set resin is applied as the resin as the shape transfer medium mentioned above, it is possible to precisely transfer the surface structure of the metal mold similarly to the case of using the ultraviolet curing resin as long as uniform hardening is achieved. As the thermo-set resin, resin commonly used for manufacturing a plastic eyeglass lens or a contact lens may be applied.

In case of applying the ultraviolet curing resin as the resin used for transferring the reversed structure of the surface structure of the metal mold, the following method for hardening the ultraviolet curing resin is preferably applied: An ultraviolet ray transmission material is selected as the material of at least one of the metal mold and the product substrate, ultraviolet rays are applied through any one or both of the metal mold and the product substrate made of ultraviolet ray transmission material during a process of hardening the ultraviolet curing resin, and thus, the ultraviolet curing resin is hardened uniformly. By uniformly hardening the ultraviolet curing resin, shape transfer performance from the metal mold is sharply improved, and thus, a precise shape transfer can be achieved.

A preferable method of hardening the resin used for transferring the reversed structure of the surface structure from the metal mold when the thermo-set resin is applied is next be described. In a state in which the metal mold and the product substrate are positioned with respect to one another, they are fixed, and a special resin injection hole is provided. During a process of hardening the thermo-set resin, while the above-mentioned combination of the metal mold and the product substrate is gradually heated, thermally hardening is performed in a manner such that heat conduction occurs uniformly throughout the entire metal mold.

Generally speaking, resin shrinks when it is hardened. Therefore, the amount of shrinkage is previously calculated. Then, it is preferable that, in a process of transferring a desired structure to a metal mold host material through dry etching of photosensitive material, the work be performed with a correction such that the structure in the metal mold host material becomes deeper with expectation of the above-mentioned previously calculated amount of shrinkage. Furthermore, it is also preferable that control be made quantitatively such that the surface flat part of the metal mold and the surface flat part of the product substrate are parallel with respect to one another and the gap therebetween becomes minimum. Thereby, it becomes possible to achieve correction in expectation of the shrinkage amount.

A preferable method for forming the fine structure in the metal mold includes the following steps g), h) and i), in the stated order:

g) applying a coat of photosensitive material (resist) onto the surface of a host material for the metal mold in which the fine structure is to be formed;

h) writing a desired shape on the photosensitive material with an electron beam (EB), developing it and thus forming the desired shape in the photosensitive material; and

i) transferring the shape in the photosensitive material thus formed to the host material for the metal mold according to a dry etching method.

By employing the way of writing the desired shape with the use of an electron beam, it is possible to produce the desired shape at high accuracy with only a single process.

Furthermore, by employing the dry etching method for transferring the shape of the photosensitive material to the metal mold host material, it is possible to transfer the structure from the resist which is soft material to the hard metal mold material.

In this case, the host material for the metal mold should be one allowing the dry etching process to be performed thereon. As this material, one selected from silicon material, semiconductor material, metal material, glass material, ceramic material, plastic material and hard rubber material may be applied.

Generally speaking, a metal mold host material is originally a flat substrate, and from a flat surface thereof, a fine structure is formed.

In case of applying a photosensitive material prepared for writing thereto with the use of an electron beam for forming a photosensitive material pattern on the metal mold host material to the metal mold itself, any one of a positive type resist and a negative type resist may be used as the photosensitive material for writing with an electron beam. In case of applying a coat of the positive type resist and performing writing processing according to an electron beam writing method in the method of producing a fine structure, advantages are provided such that the repeatability in writing is superior, and also, control of a leak of the electron beam is easier and thus the control of the writing process is easier.

When producing the metal mold, during a process in which the structure of the photosensitive material is transferred to the metal mold host material according to a dry etching method, it is preferable to change the selectivity stepwise or continuously so as to transfer the desired structure in a manner in which the transfer occurs more in the depth direction (so that the aspect ratio becomes large accordingly). By stepwise or continuously changing the selectivity, it becomes possible to obtain the desired structure in the metal mold more deeply. There, the term ‘metal mold’ means a thing which has a basic structure, and thus, means ‘an original which has a basic structure to be transferred’. Although no details are described here, it is also possible that, based on the above-mentioned ‘metal mold’ (mother mold), another metal mold (sister mold) is produced (although the structure is reversed) according to an electroforming method, and the thus-obtained sister mold may be used as the metal mold for transferring the hyperfine structure for an embodiment according to the second aspect of the present invention. In this case, there is no special limitation in the material, and a metal, an alloy material or so may be applied as long as plating can be made on the material.

As the metal material used for forming a film on the product substrate, aluminum (Al) which has a high reflectance performance is preferable. The fine structure in the polarization optical device according to the embodiment is created according to a process in which the resin structure once transferred from the metal mold is further transferred to the surface of the thus-formed metal layer.

In a case of transferring the structure once transferred to the resin from the metal mold then to the product substrate according to a dry etching method, it is preferable to change stepwise or continuously the etching selectivity between the resin and the product substrate in the dry etching process for the purpose of forming a desired shape in the product substrate. Through adjustment of the selectivity, it is possible to correct the shape in the depth direction, and thus, it becomes possible to transfer the desired deep shape. Furthermore, it is possible to achieve flatness of the surface of the substrate by terminating the etching process (for transferring the hyperfine structure) on the way so as to leave a little of the resin layer on the surface of the substrate, and then, removing the thus left resin part together with a seed layer.

As a method of filling in metal grove parts in the three-dimensional hyperfine structure formed in the product substrate with a film of silicon dioxide (SiO₂) as the protective layer, a vacuum deposition method, a CVD (chemical vapor deposition) method or a sputtering method may be applied. In this regard, W (tungsten) or Cu (copper) has been proposed as a material used for filling in through holes of 0.1 μm (=100 nm) in the semiconductor integrated circuit manufacturing field. However, in the polarization optical device also according to the second aspect of the present invention, since various requirements should be satisfied, i.e., (i) the line width of each line may become further reduced to less than 100 nm, (ii) silicon dioxide material having a low refractive index is preferably applied, (iii) positive filling-in performance is required, (iv) bubbles should not occur in the material thus embedded, and so forth, there may occur a problem if the conventional method of simply forming a film of silicon dioxide is applied as it is.

Thus, in a preferable method according to the second aspect of the present invention, a plasma CVD method or a sputtering method is applied for filling in the hyperfine structure produced with silicon dioxide as a preferable material with high throwing power. According to the second aspect of the present invention, silicon dioxide is thus applied as a material for filling in the hyperfine structure of the array of strips of conductive elements made of a metal pattern of aluminum, for example, since silicon dioxide has a low refractive index, and is superior for being applied to a fine structure with high throwing power. According to the plasma CVD method, a film of silicon dioxide is formed on the product substrate with the use of a common semiconductor manufacturing apparatus, and with the use of silane gas or TEOS (tetra ethyl ortho silicate) gas as a reaction gas.

As the sputtering method, a common sputtering method employing silicon dioxide as a sputtering target may be applied. Alternatively, it is also possible to apply a digital sputtering method (rotational carousel type film forming method) wherein after silicon (Si) is sputtered, it is oxidized.

A preferable method for forming the protective layer made of silicon dioxide includes the following steps of, in the stated order:

j) performing hydrogen processing or oxygen processing on the surface of the product substrate having the array of strips of conductive elements for improving the adhesiveness;

k) forming a film of silicon dioxide until depression zones among the strips of conductive elements are completely filled in therewith; and

l) further growing the silicon dioxide film to a height higher than the height of the array of strips of conductive elements after completely filling in the depression zones among the strips of conductive elements.

Thereby, it is possible to improve the adhesiveness of the product substrate and the array of strips of conductive elements with respect to the protective layer made of silicon dioxide, and also, to positively fill in the grooves occurring among the strips of conductive elements.

In the manufacturing method according to the second aspect of the present invention, the surface of the product substrate is thus covered by the silicon dioxide since a protective layer is thus formed thicker than the array of strips of conductive elements. However, since the film of the protective layer may not necessarily be formed uniformly throughout the entire surface of the substrate during the growth of the protective layer, the surface morphology may be roughened on the order of several nanometers through several tens of nanometers in a microscopic view. In order to eliminate this roughness and provide parallelism with respect to the surface of the substrate, a polishing/grinding process method or a CMP method may be applied to polish or grind the surface so as to provide flatness there.

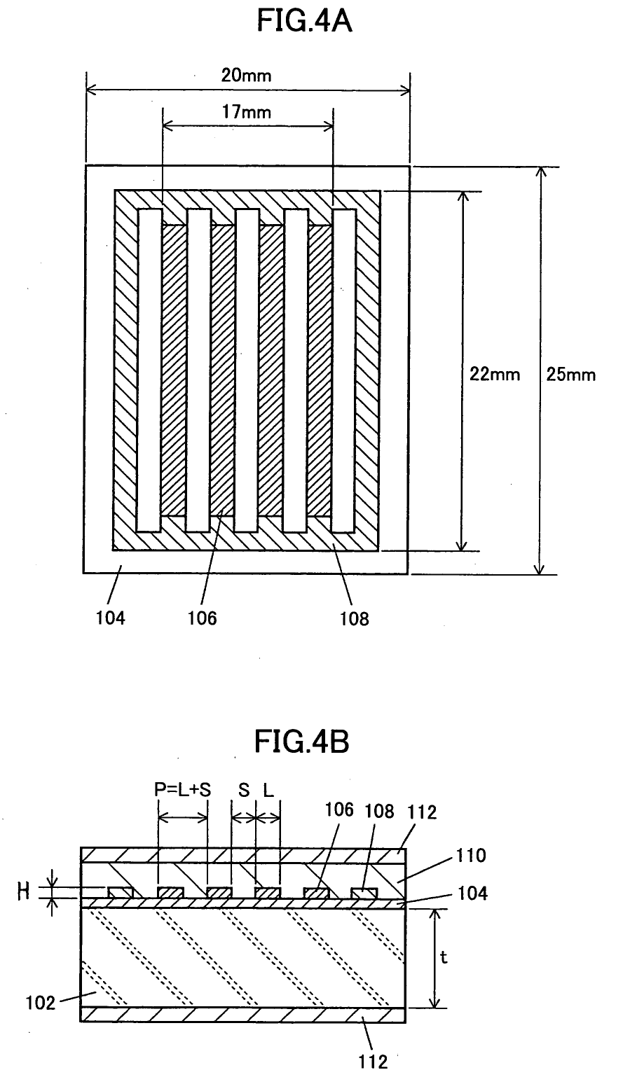

Actual embodiments (second through fifth embodiments) according to the second aspect of the present invention are next described. In a second embodiment of the present invention, a polarization optical device as shown in FIGS. 4A and 4B was produced.

This polarization optical device has a configuration in which an undercoat layer 104 made of silicon dioxide is formed on a surface of a product substrate 102 made of synthetic quartz substrate having the thickness ‘t’ of 1.0 mm. On the under coat layer 104, conductive elements 106 made of an aluminum pattern are arranged in the form of an array with a land and space L/S of 35 nm/35 nm, a pitch P of 70 nm and a height H of 110 nm. The product substrate 102 has a size of 25 mm×20 mm as shown, and an effective area of the device is 22 mm×17 mm. In the array, the conductive elements 106 with the above-mentioned L/S are arranged in a regular pattern parallel to the longitudinal direction of the substrate 102. ‘L’ (line) denotes a part in which the conductive element 106 is formed, while ‘S’ (space) denotes a zone between adjacent conductive elements 106. ‘P’ denotes the pitch of L+S. In the figures, the polarization optical device is shown in a manner in which only the four lines (L) of conductive elements 4 are illustrated in a magnified manner for the purpose of simplification (in other words, actually, the repetitive pattern of the L/S is so fine that it is not possible to show it in the figure if drawn according to the actual dimensions mentioned above).

In an area having a width of several millimeters surrounding the conductive element array, a belt-like zone exists in which no conductive element 4 appears. In this area, a conductive layer 108 connected to the conductive elements 106 is formed on the undercoat layer 104. The conductive layer 108 is an aluminum film as in the conductive elements 106, and can be produced at the same time in which the conductive elements 106 are formed.

On the undercoat layer 104, the conductive elements 106 and the conductive layer 108, a protective layer 110 is formed. The protective layer 110 has a thickness of 0.5 μm.

On both obverse and reverse sides of the polarization optical device, reflection preventing films 112 are formed. Each of the reflection preventing films 112 is a film having five layers including, for example, in the order from the product substrate 102 or from the protective layer 110, an SiO₂ film, a TiO₂ film, a SiO₂ film, a TiO₂ film and an MgF₂ film, each film of which has a thickness of λ/4 (where λ is a central wavelength of a range between 380 and 700 nm, and in this case, λ=540 nm), i.e., 135 nm. A range of wavelength for which each of these reflection preventing films 112 has a reflection preventing function is the range between 380 and 700 nm, and the transmittance there is more than 99% when the transmittance of the quartz substrate 102 is assumed as 100%.

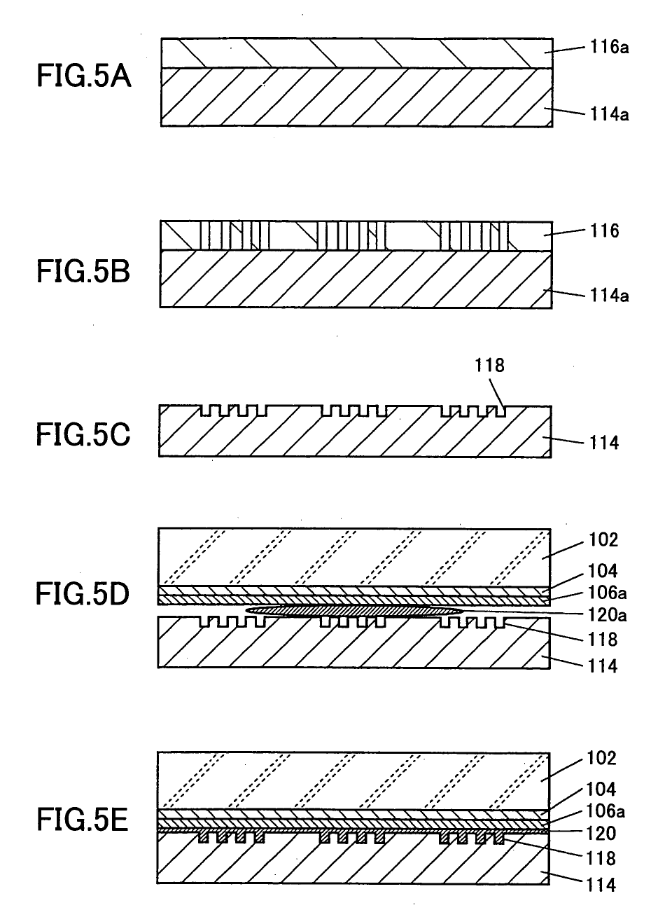

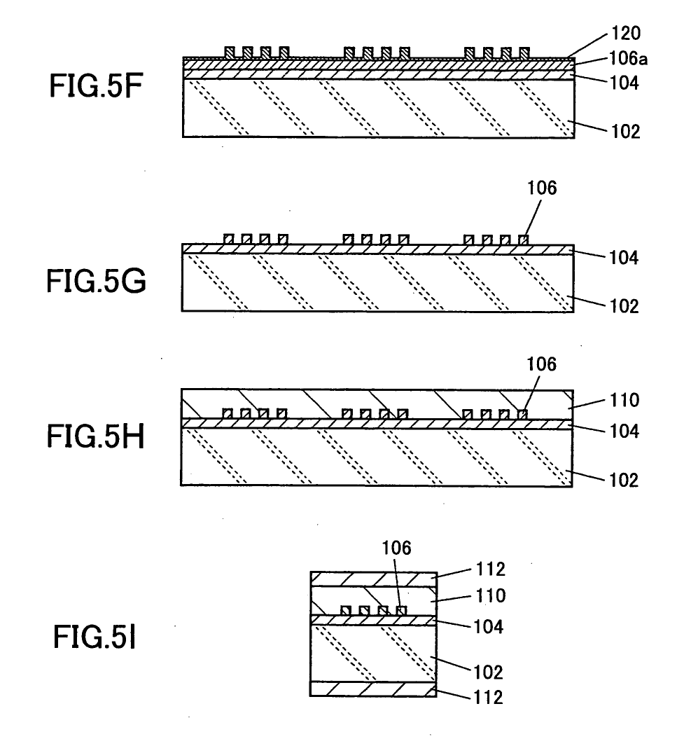

FIGS. 5A through 5I illustrate a manufacturing procedure for this polarization optical device in the second embodiment of the present invention.

In a step of resist coating and writing shown in FIG. 5A, photosensitive material prepared for an electron beam writing process was applied to form a coat on a metal mold host material, and then writing was performed with the use of an electron beam.

Specifically, as the metal mold host material 114a, a silicon substrate having a diameter of 6 inches and a thickness of 1.0 mm was prepared. On the surface of this metal mold host material 114a, photosensitive material (resist) 116a (ZEP-520 made by Zeon corporation) prepared for an electron beam writing process was applied to form a coat with the use of a spinner for five seconds at 500 rpm and then, for 30 seconds at 4000 rpm. Then, after pre-baking was performed for five minutes at 90° C., rapid cooling was performed. At this time, the film thickness of the resist 116a resulting therefrom was 140 nm.

Then, in order to obtain a reversed structure (projections and depressions are reversed) of the structure shown in FIGS. 4A and 4B, data of area separation, paths, a beam diameter, a dose amount, a writing time and so forth for tracing by means of an EB application beam were previously input to a personal computer with the use of special software. Also in this embodiment, the entire area for writing was divided into square areas each having a size of 500 μm×500 μm, a writing program was produced, and finally, writing for the entire area of 22 mm×17 mm was achieved by repeating a writing process for the above-mentioned divided area and connecting these divided areas together side by side. In this embodiment, the structure in the final product and the writing structure have a reversal relationship therebetween. For this purpose, the software program for the reversed structure should be produced accordingly.

The metal mold host material 114a having the resist 116a coated thereon was set in an electron beam writing apparatus, and then, the air in the apparatus was evacuated into a predetermined vacuum. After that, the special data input as mentioned above was transferred to a control unit of this writing apparatus, and then, a writing process with the use of an electron beam was started in this apparatus. Also in this embodiment, writing was performed while an X-Y stage on which the metal mold host material was placed was moved. The writing process required 48 hours as a result.

Then, the process of developing and rinsing shown in FIG. 5B was performed. FIG. 5B illustrates a cross-sectional view of a pattern after a developing process was performed.

After the above-mentioned writing process, with the use of developer (ZEP-520 developer), developing was performed for three minutes at 25° C. Then, rinsing was performed, and immediately after that, drying was performed with the use of a nitrogen blower while rotation was performed by the spinner. Furthermore, post-baking was performed for five minutes at 120° C. As a result, the photosensitive material (resist) 116 was shaped into a desired pattern 116 for the hyperfine structure on the metal mold host material 114a.

Then, a process of producing the metal mold in dry etching with the use of the photosensitive material 116 thus shaped into the pattern as a mask, and then, removing the photosensitive material as the necessity arose, was performed as shown in FIG. 5C.

The pattern 116 (hyperfine structure) of the resist formed through the writing process was then transferred into the metal mold host material 114a according to a dry etching method. Thus, the metal mold 114 was formed. In the dry etching process, etching was performed with the use of a TCP (induction coupled plasma) etching apparatus, while gas of CF₄ was introduced at 20 sccm, with a substrate bias voltage of 500 V, with a top electrode power of 1250 W and vacuum of 1.0×10⁻³ Torr (i.e., 1.0 mTorr) for 0.5 minutes. At this time, the etching rate was 180 nm/minute. The etching was finished in a state of a small amount (on the order of 10 nm) of under etching. That is, a small amount of the resist remained on the surface of the metal mold 114. The selectivity (the etching rate for the metal mold host material/the etching rate for the resist) in the etching was 1.0, and the depth of each depression 118 (see FIG. 5C) in the metal mold 114 resulting from the etching was 120 nm. The surface roughness Ra on the surface was less than 2 nm, and thus, was sufficiently low. This depth of the depression 118 was previously set in expectation of being selectivity applied in a subsequent process and a resin shrinkage ratio (7%). At this time, the depression 118 had the same pitch and only the depth was changed by 0.9 times (depression 118 depth×0.9 =height H of conductive element 106), with respect to the state immediately after undergoing the writing process mentioned above.

Then, in order to perform mold releasing processing on the surface of the metal mold 114, surface treatment was performed with a triazin thiol organic compound having a fluorine functional group. This process was performed according to a method called the organic galvanizing method. Specifically, electrolytic polymerization processing (organic galvanizing) was performed in a solution in which a fluorinated SFTT (super fine triazin thiol) was dissolved in solvent, and thus, a fluorine organic thin film was formed on the surface of the metal mold. The above-mentioned fluorinated SFTT is one which is obtained from fluorinating a side chain of triazin thiol which is one of organic sulfur compounds. Since, as to the number ‘n’ of the fluorine molecules, n=7 provided the most water repellent effect (mold releasing effect), this condition was thus applied, and the film was thus formed for 10 nm in thickness.

Then, the process of FIG. 5D was performed in which resin was applied onto the metal mold pattern, and then, a product substrate was pressed thereto from the top as shown.

On a product substrate 102 made of synthetic quartz (synthetic quartz, SUPRASIL-P-20, made by Shi-Etsu Chemical, Co., Ltd.), an undercoat layer 104 made of silicon dioxide was formed according to a sputtering method for a thickness of 100 nm for the purpose of improving adhesiveness, and further, thereon, an aluminum film 106a was formed for a thickness of 110 nm according to a sputtering method. After that, as the necessity arose, heating reflow processing was performed in a sputtering chamber with the use of a heater at 350° C. so that the aluminum was flattened.

The metal mold 114 having undergone the mold releasing process as discussed above was set first, and then, on top of the metal mold 114, acrylic resin (GRANDIC RC-8720 made by Danippon Ink and Chemicals, Incorporated) as ultraviolet curing resin 120a which is the preferable resin was applied as a coat by 1 cc. Then, this metal mold 114 was set in a special bonding machine, and then, the above-mentioned product substrate 102 which previously had undergone silane coupling processing (processing for improving the adhesiveness) in a separate process on the surface of the above-mentioned aluminum film 106a was slowly pressed onto the surface of the product substrate 114 with the surface thereof having undergone the silane coupling processing applied to the metal mold 114. At this time, the automatic bonding machine was used by which the lowering speed of the product substrate 102 and the parallelism between the metal mold 114 and the product substrate 102 (so that the gap therebetween becomes less than 50 nm) were controlled so that generation of bubbles in the ultraviolet curing resin 120a was avoided.

Then, the metal mold 114 was slowly pressed up onto the product substrate 102 from the bottom side, and a part of the ultraviolet curing resin 120a which was extraneous to structure transfer processing was removed.

Then, the process of FIG. 5E was performed in which the ultraviolet curing resin was hardened.

In this process, from the side of the metal mold 114, uniform ultraviolet rays of 3000 mJ were applied, and thus, the ultraviolet curing resin 120a was hardened. At this time, the thickness of the ultraviolet curing resin 120a (the distance between the top of the metal mold 114 and the aluminum film 106a of the product substrate 102) was less than 50 nm. Accordingly, the maximum height of the ultraviolet curing resin 120 was less than 170 nm (=the above-mentioned pattern depth of 120 nm+the above-mentioned distance of less than 50 nm).

Then, the process of FIG. 5F was performed in which the metal mold 114 was separated from the product substrate 102.

Specifically, in order to separate the ultraviolet curing resin 120 from the metal mold 114 in a state in which the ultraviolet curing resin 120 was bonded to the product substrate 102, a jig was used, and, while the metal mold 114 was slightly deformed to be bent into a convex form, the separation was achieved with maintaining the parallel state therebetween.

When the hyperfine structure thus transferred to the resin layer 120 on the surface of the product substrate 102 was measured, the height of the projection corresponding to the depression 118 of the metal mold 114 was 110 nm at this time reduced from the above-mentioned depth of 120 nm in the depression 118. This is because the resin layer 120 shrank while being hardened. Thus, the shrinkage ratio was approximately 8.5%.

The process of FIG. 5G was then performed in which the resin structure (hyperfine structure) was transferred to the aluminum film 106a on the surface of the product substrate 102 according to a dry etching method.

Specifically, the structure once transferred to the resin layer 120 on the aluminum film 106a on the product substrate 102 was transferred to the aluminum film 106a, and thus, the above-mentioned conductive elements 106 and the conductive layer (omitted in the figure) were created. In this dry etching process, etching was performed with the use of a TCP (induction coupled plasma) etching apparatus, while gas of BCl₃ in 15 sccm, CF₄ in 10 sccm and Ar in 5 sccm was introduced, with a substrate bias voltage of 500 V, with a top electrode power of 1250 W and vacuum of 1.0×10⁻³ Torr (i.e., 1.0 mTorr) for 1.3 minutes. At this time, the etching rate was 100 nm/minute for the aluminum.

The etching was finished in a state of a little (on the order of 40 nm for example) under etching for the resin layer 120. That is, a small amount of the resist remained on the surface. For the aluminum film 106a, the etching was finished in a state of over etching on the order of 40 nm, for example. That is, the aluminum film 106a in the unnecessary zones was completely removed, and thus, the conductive elements 106 and the conductive layer were created. The selectivity (the etching rate for the product substrate/the etching rate for the resist layer) in the etching was 1.3, and the height of the conductive elements 106 obtained from the etching was 110 nm. After that, the remaining resin organic material layer was removed through oxygen ashing. The surface roughness Ra on the surface was less than 2 nm, and thus, was sufficiently low.

The hyperfine structure (conductive elements) 106 resulting from the etching was measured with the use of a measuring SEM apparatus. Specifically, the L/S widths and step heights were measured. In this intermediate process, as the optical device structure thus obtained in the intermediate process, the array of conductive elements 106 and the conductive layer (omitted from the figure) were produced in which L/S=35/35 nm, P=70 nm and the height H=110 nm on the surface of the silicon oxide material 104 on the product substrate 102.

The process of FIG. 5H was then performed in which, according to a plasma CVD method, the aluminum grooves between the conductive elements 106 were filled in with a silicon dioxide film.

With the use of a plasma CVD apparatus, a protective layer 110 made of silicon dioxide was formed on the order of 2.5 μm thickness on the undercoat layer 104 including the conductive elements 106. At this time, the grooves occurring among the conductive elements 106, and the grooves between the conductive elements 106 and the conductive layer were completely filled in with the protective layer 110. With the use of an SEM (electron microscope), the substrate's cross-sectional view was observed. As a result, the hyperfine patterns of the conductive elements 106 were completely filled in, and also, no defect such as bubbles or so inside of the protective layer 110 were found.

Then, the same as in a common glass plate grinding process, with the use of a grinding sheet material having diamond particles embedded therein caused to uniformly adhere to a grinding plate which underwent surface grinding to an accuracy of less than 300 nm in flatness, a grinding condition was changed such that the size of the above-mentioned diamond particles was changed from #800 to #1200 and then to #2000; thus, the particle diameter became gradually reduced, as the surface of the protective layer 110 was ground. After the grinding, the surface roughness Ra of the protective layer 110 became less than 2 nm and thus, was sufficiently low.

Then, the process of FIG. 5I was performed in which the reflection preventing films 112 were formed on the surface of the protective layer 110 and the surface of the product substrate 102 opposite to the protective layer 110.

Until then, the processes were performed on a single substrate in which a plurality of polarization optical devices were formed; next, it was finally cut and separated into the particular polarization optical devices for providing actual products by means of a dicing apparatus.

For the thus-obtained particular polarization optical devices, the pattern dimension and the optical performance were measured. Specifically, in the product inspection, in a sampling manner, cross-sectional structure evaluation was performed and dimensional measurement was performed with the use of a measuring SEM apparatus. According to the above-described manufacturing method, the polarization performance of the transmittance of 90%, and the contrast of 1200 (λ=450 nm) was obtained according to the designed values.

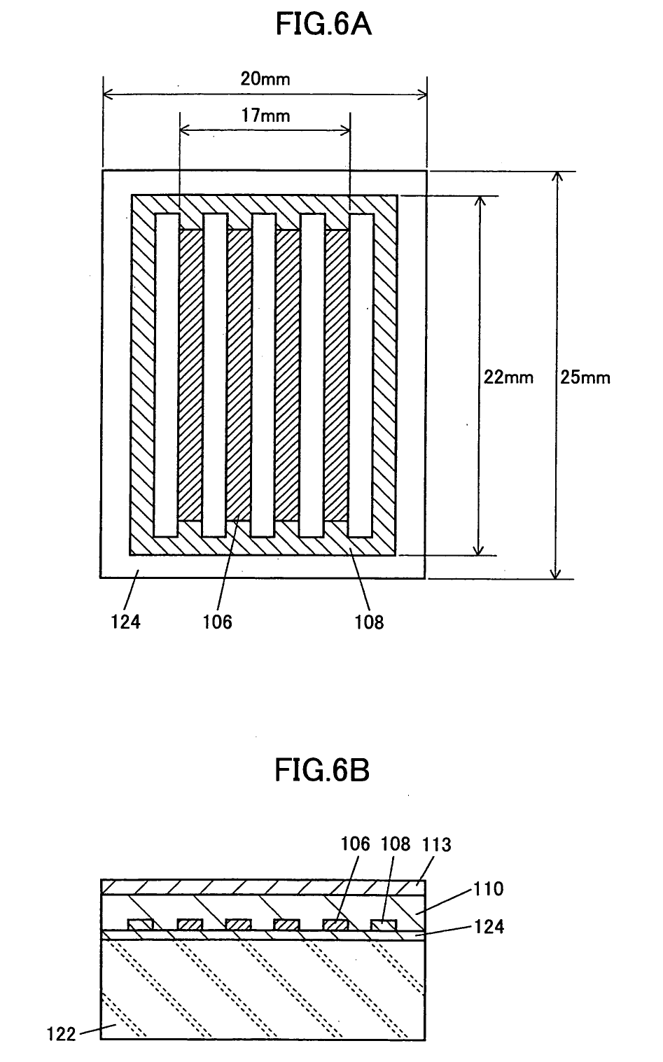

A third embodiment according to the above-mentioned second aspect of the present invention is next described. In the third embodiment of the present invention, a polarization optical device as shown in FIGS. 6A and 6B was produced. In the figures, for the same parts as those in the second embodiment described above, the same reference numerals are given, and the duplicated descriptions therefor are omitted.

This polarization optical device has a configuration in which an undercoat layer 124 having a thickness of 405 nm is formed on a surface of a product substrate 122 made of an optic glass (BK-7) substrate having a thickness of 1.0 mm. The undercoat layer 124 is a film including three layers of an SiO₂ film, a TiO₂ film and an SiO₂ film in the stated order from the bottom each having a thickness of 135 nm, has adhesiveness with respect to both the substrate 122 and metal material, and also, has a reflection preventing function.

The same as in the second embodiment described above with reference to FIGS. 4A and 4B, conductive elements 106 and conductive layer 108 are formed. Also in this case, the same as in the case of the second embodiment, the conductive elements 106 are shown in a magnified and simplified state with only four of the conductive elements 106 for the purpose of simplification.

On the undercoat layer 124 including the conductive elements 106 and the conductive layer 108, a protective layer 110 made of silicon dioxide is formed. The thickness of the protective layer 110 is, for example, 0.8 μm.

On the surface of the protective layer 110, a reflection preventing film 113 is formed which has a laminated structure including three layers, i.e., from the bottom, in the stated order, an Al₂O₃ film (135 nm), a ZrO film (270 nm) and an MgF₂ film (135 nm). In this embodiment, different from the above-described second embodiment, no reflection preventing film is formed on the surface of the substrate 122 opposite to the protective layer 110. However, also in this embodiment, a reflection preventing film may be formed on the surface of the substrate 122 opposite to the protective layer 110.

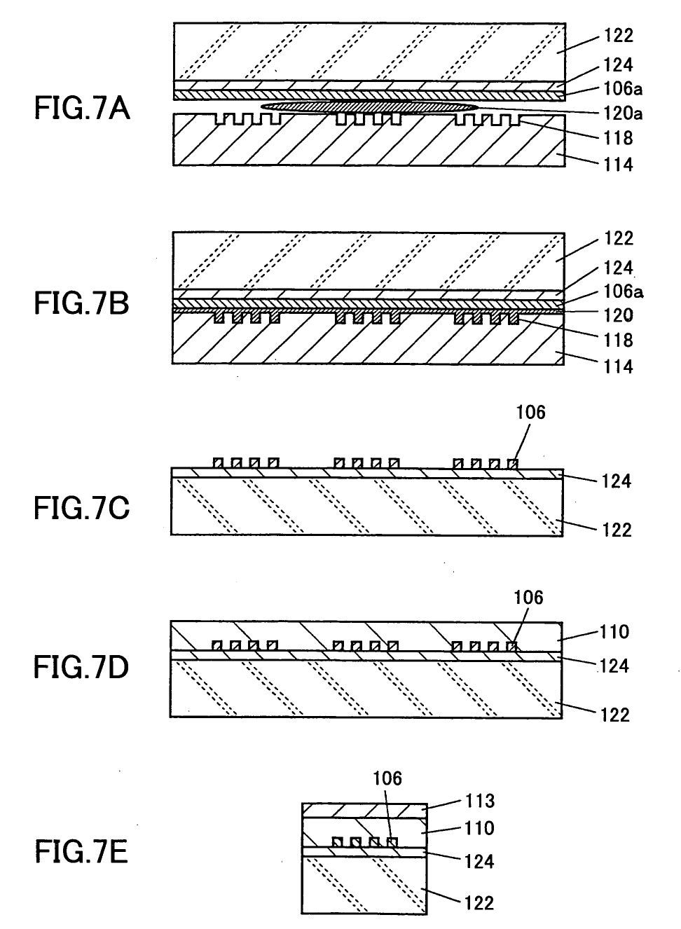

A manufacturing procedure for manufacturing the polarization optical device in the third embodiment described above is next described with reference to FIGS. 7A through 7E.

First, a metal mold 114 was formed having depressions 118 in the same processes as those described above for the second embodiment with reference to FIGS. 5A through 5C.

On the other hand, for the purpose of improving the adhesiveness and reflection prevention performance, a film having a three layer laminated structure including, in the stated order from the bottom, an SiO₂ film, a TiO₂ film and an SiO₂ film each having a thickness of 135 nm was designed with the use of optical designing the software same as that prepared for the reflection preventing film, and the undercoat layer 124 having functions according to this design was formed according to a vacuum deposition method on a surface of a product substrate 122 made of BK-7. Further, thereon, an aluminum film 106a having a thickness of 110 nm was formed according to a sputtering method. In this embodiment, no heating reflow processing was performed.

Then, the process of FIG. 7A was performed the same as in the above-described process described above with reference to FIG. 5D, in which an ultraviolet curing resin 120a was formed in a coat on the metal mold 114, and then, after the surface of the aluminum film 106a of the product substrate 122 previously having undergone silane coupling processing in a separate process was bonded with the ultraviolet curing resin 120a, an extra part of the ultraviolet curing resin 120a was removed.

Then, in a process shown in FIG. 7B, the same as the process described above with reference to FIG. 5E, the ultraviolet curing resin 120a was hardened, and thus, a resin layer 120 was formed. At this time, the ultraviolet curing resin layer 120 had the thickness less than 50 nm, and the maximum thickness of the ultraviolet curing resin layer 120 was less than 170 nm.

In the process shown in FIG. 7C, in the same process as that described above with reference to FIG. 5F, the ultraviolet curing resin layer 120 was separated from the metal mold 114 in a state in which the bonding of the resin layer 120 to the product substrate 122 was maintained.

Then, the structure thus transferred to the resin layer 120 on the aluminum film 106a on the product substrate 122 was further transferred to the aluminum film 106a, and thus, the conductive elements 106 and the conductive layer (omitted from the figure) were formed. In the dry etching for performing this transfer process, a TCP etching apparatus was used, while gas of BCl₃ at 15 sccm, CF₄ at 10 sccm and Ar at 5 sccm was introduced, the etching was performed for 1.0 minute with a substrate bias voltage of 500 V, an upper electrode power of 1250 W and vacuum of 1.0×10⁻³ Torr. At this time, the etching rate for the aluminum was 130 nm/minute.

For the resin layer 120 at this time, the etching was terminated in a state of under etching on the order of 40 nm, for example. That is, a small amount of the resin remained on the surface. For the aluminum, the etching was terminated in a state of over etching on the order of 40 nm, for example. In other words, the unnecessary aluminum was completely removed. The etching selectivity (etching rate for the product substrate/etching rate for the resin layer) was 1.2, and the height of the conductive elements 106 thus created after the etching was 110 nm. After that, the remaining resin organic material layer was removed through common oxygen ashing. The surface roughness Ra was less than 2 nm, and thus, was sufficiently low.

Then, a measuring SEM apparatus was used for measuring L/S widths and step height. As a result, in this intermediate process, the optical device structure was such that the array of conductive elements 106 and the conductive layer (omitted from FIG. 7C) were produced with L/S of 35/35 nm, P of 70 nm and the height H of 110 nm on the undercoat layer 124 on the product substrate 102.

Then, in the process shown in FIG. 7D, with the use of a digital sputtering apparatus (carousel type sputtering apparatus), a protective layer 110 made of silicon dioxide was formed for a thickness of on the order of 2.5 μm on the undercoat layer 124 including the conductive elements 106. The digital sputtering apparatus used in this process includes two rooms, i.e., a target material sputtering film forming room (first room) and a plasma processing room (second room). Then, a configuration is made such that a cylindrical substrate holder jig is rotated at high speed. In this embodiment, a film of an Si material was formed for a thickness of a single molecular layer in the first room, and, in the second room, the Si molecular layer was oxidized through plasma oxidization. By repeating this processing at high speed, a stable silicon dioxide film could be formed for the protective layer 110.

By this processing, grooves among the conductive elements 106 and grooves between the conductive elements 106 and the conductive layer were completely filled in with the protective layer 110, and this matter was confirmed in a substrate cross-sectional view observation with the use of an SEM after the film forming. The hyperfine patterns of the conducive elements 106 were thus completely filled in, and also no defect such as bubbles or so were found inside of the protective layer 110 in this observation.

Then, in the same grinding process as that described above with reference to FIG. 5F, the surface of the protective layer 110 was ground. The surface roughness Ra of the protective layer 110 after the grinding was less than 2 nm, and thus was sufficiently low.

Then, in the process shown in FIG. 7E, a reflection preventing film 113 was formed on the surface of the protective layer 110. Finally, for providing actual products, the substrate was cut and separated with the use of a dicing machine into individual polarization optical devices.

Then, the pattern size and the optical performance in the thus-obtained polarization optical device were evaluated. As a result, according to the above-described manufacturing method according to the third embodiment, according to the design, the polarization performance of the transmittance of 83%, and the contrast of 600 (λ=450 nm) was obtained.

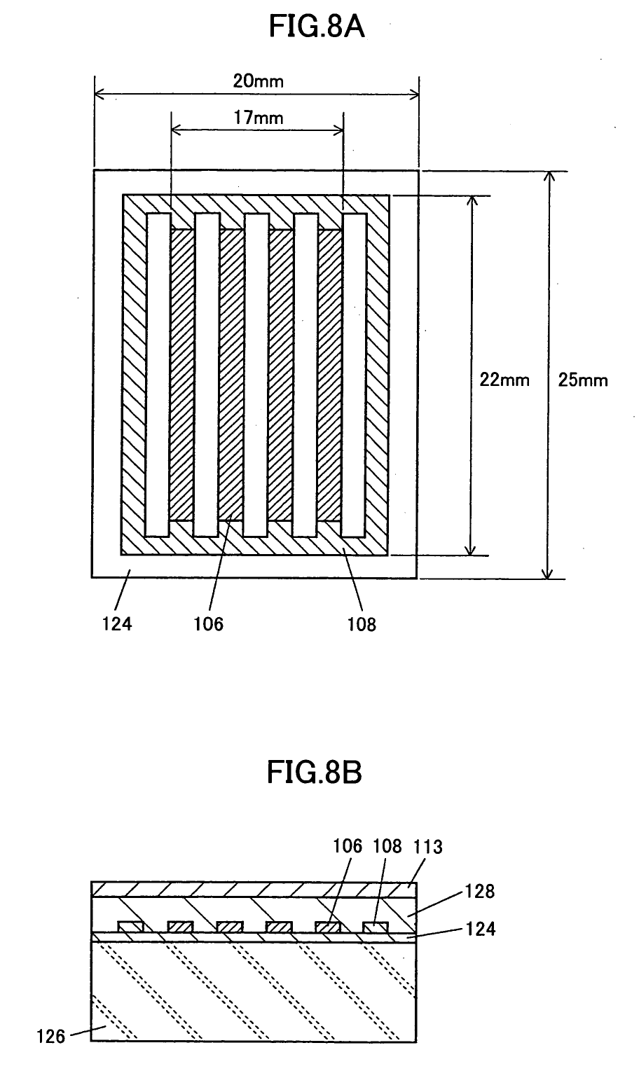

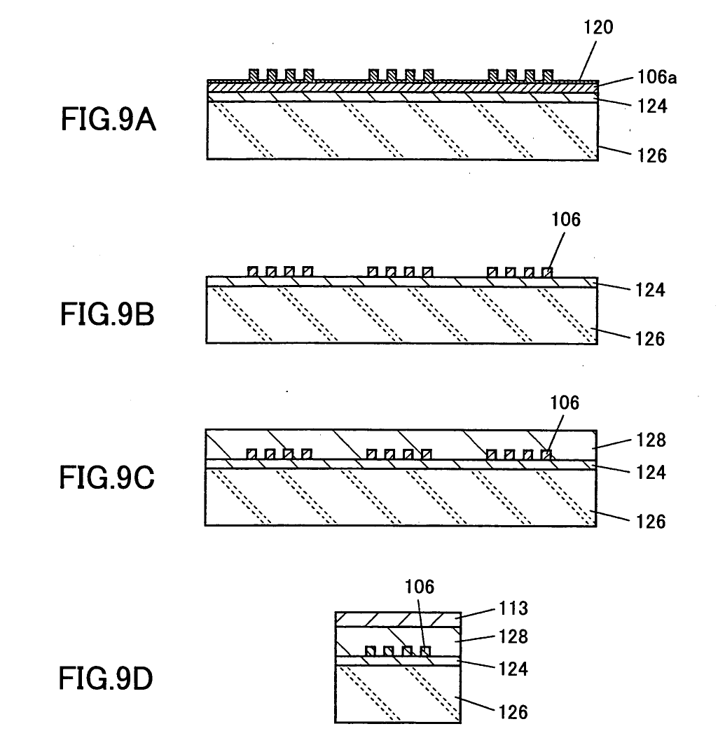

A fourth embodiment according to the above-mentioned second aspect of the present invention is next described with reference to FIGS. 8A and 8B for a polarization optical device, and FIGS. 9A through 9D for a manufacturing procedure therefor. In the part/components the same as those shown FIGS. 4A, 4B, 6A and 6B, the same reference numerals are given and duplicate descriptions thereof are omitted.

In the fourth embodiment, on a surface of a product substrate 126 made of a quartz substrate having a thickness of 1.0 mm, an undercoat layer 124 having a thickness of 100 nm is formed. The undercoat layer 124 is the same as the undercoat layer 124 shown in FIGS. 6A and 6B in the third embodiment, and has adhesiveness with respect to the product substrate 126 and metal material, and a reflection preventing function.

On the undercoat layer 124, the conductive elements 106 and the conductive layer 108 having the same configurations as those in the second and third embodiments described above with reference to FIGS. 4A, 4B, 6A and 6B are formed. Also in FIGS. 8A and 8B, for the purpose of simplification, the conductive elements 106 are shown in a magnified and simplified manner and only four pieces thereof are shown.

On the undercoat layer 124 including the conductive elements 106 and the conductive layer 108, a protective layer 128 made of a mixed material of silicon dioxide and niobium oxide is formed. The protective layer 128 has, for example, a thickness of 0.5 μm and a mixing ratio between the silicon dioxide and niobium oxide is, for example, 100:1.

On the surface of the protective layer 128, a reflection preventing film 113 is formed. In this embodiment, different from the above-described second embodiment, no reflection preventing film is formed on the surface of the substrate 126 opposite to the protective layer 128. However, also in this embodiment, a reflection preventing film may be formed on the surface of the substrate 126 opposite to the protective layer 128.

A manufacturing procedure for manufacturing the polarization optical device in the fourth embodiment described above is next described with reference to FIGS. 9A through 9E.

First, a metal mold 114 was formed having depressions 118 in the same processes as those described above for the second embodiment with reference to FIGS. 5A through 5C.

The same as the above-described process described with reference to FIG. 7A for forming the undercoat layer 124, an undercoat layer 124 was formed on a surface of a product substrate 126. Further, thereon, an aluminum film 106a of a thickness of 110 nm was formed by a sputtering method. After that, as the necessity arose, heating reflow processing was performed in the sputtering chamber with the use of a heater at 350° C. for the purpose of flattening the aluminum.

Then, in the process same as the process described above with reference to FIG. 5D, ultraviolet curing resin 120a was formed as a coat on the metal mold 114, and then, after the surface of the aluminum film 106a of the product substrate 126 previously having undergone silane coupling processing in a separate process was bonded with the ultraviolet curing resin 120a, the extra part of the ultraviolet curing resin 120a was removed.

Then, in a process the same as the process described above with reference to FIG. 5E, the ultraviolet curing resin 120a was hardened, and thus, a resin layer 120 was formed. At this time, the ultraviolet curing resin layer 120 had a thickness less than 50 nm as in the above-mentioned process described with reference to FIG. 5E, and the maximum thickness of the ultraviolet curing resin layer 120 was less than 170 nm.

In a process the same as that described above with reference to FIG. 5F, the ultraviolet curing resin layer 120 was separated from the metal mold 114 in a state in which the bonding of the resin layer 120 to the product substrate 126 was maintained (see FIG. 9A). When the structure transferred to the resin layer 120 on the aluminum film 106a on the product substrate 126 as shown in FIG. 9A was measured, the height of the projections corresponding to the depressions 118 in the metal mold 114 was 110 nm, and thus, was reduced from the depth of the depressions 118.

Then, in a process shown in FIG. 9B, in the same process as that described above with reference to FIG. 5G, the structure transferred to the resin layer 120 on the aluminum film 106a on the product substrate 126 was then further transferred to the aluminum film 106a, and thus, conductive elements 106 and a conductive layer (omitted from the figure) were formed. After the etching of this transfer process, the structure height of the conductive elements 106 was 110 nm. After that, the resin organic material thin layer that remained was removed through common oxygen ashing. The surface roughness Ra was less than 2 nm, and thus, was sufficiently low.

Then, a measuring SEM apparatus was used for measuring L/S widths and step height. As a result, in this intermediate process, the optical device structure was such that the array of conductive elements 106 and the conductive layer (omitted from the figure) were produced with L/S of 35/35 nm, P of 70 nm and the height H of 110 nm.

Then, in a process shown in FIG. 9C, with the use of a digital sputtering apparatus (carousel type sputtering apparatus), a protective layer 128 made of silicon dioxide having niobium oxide slightly mixed therein and having a refractive index of 1.55 was formed for a thickness of on the order of 2.5 μm on the undercoat layer 124 including the conductive elements 106 and the conductive layer. The digital sputtering apparatus used in this process includes three rooms, i.e., target material sputtering film forming rooms (first and second rooms) and a plasma processing room (third room), wherein a configuration is made such that a cylindrical substrate holder jig is rotated at high speed. In this embodiment, a film of an Si material was formed for a thickness of a single molecular layer in the first room, a film of niobium was formed in the second room, and, in the third room, the Si+Nb molecular layer was oxidized through plasma oxidization. By repeating this processing at high speed, the stable silicon dioxide+niobium oxide film could be formed.

By this processing, grooves among the conductive elements 106 and grooves between the conductive elements 106 and the conductive layer were completely filled in with the protective layer 128 and this matter was confirmed in substrate cross-sectional view observation with the use of an SEM after the film forming. The hyperfine patterns of the conducive elements 106 were thus completely filled in, and also no defects such as bubble generation or so were found inside of the protective layer 128.

Then, in the same grinding process as that described above with reference to FIG. 5H, the surface of the protective layer 128 was ground. The surface roughness Ra of the protective layer 128 after the grinding was less than 2 nm, and thus was sufficiently low.

Then, in a process shown in FIG. 9D, a reflection preventing film 113 was formed on the surface of the protective layer 128. Finally, for providing actual products, the substrate was cut and separated with the use of a dicing machine into individual polarization optical devices. Then, the pattern size and the optical performance in the thus-obtained polarization optical devices were evaluated. As a result, according to the above-described manufacturing method according to the fourth embodiment, according to the design, the polarization performance of the transmittance of 65% and the contrast of 200 (λ=450 nm) was obtained.

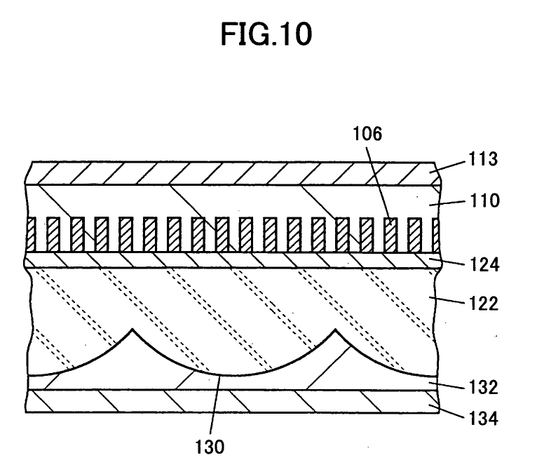

FIG. 10 shows a fifth embodiment according to the above-mentioned second aspect of the present invention. In FIG. 10, the same reference numerals are given to parts the same as those shown in FIGS. 6A and 6B, and the duplicate descriptions thereof are omitted. In FIG. 10, a part of a polarization optical device is shown in a magnified manner.

An undercoat layer 124 having adhesiveness and a reflection preventing function is formed on a surface of a product substrate 122 made of a BK-7 substrate. On the undercoat layer 124, conductive elements 106 and a conductive layer (omitted from the figure) are formed. Then, on the undercoat layer 124 including the conductive elements 106, a protective layer 110 is formed. On the surface of the protective layer 110, a reflection preventing film 113 is formed.

A micro lens array 130 is formed on the surface of the product substrate 122 opposite to the protective layer 110 (referred to as a reverse surface, hereinafter). On the micro lens array 130, a cover glass 134 is provided via a resin layer 132 as shown.

In the fifth embodiment, on the obverse surface of the product substrate. 122, an array of the conductive elements 106 are provided via the undercoat layer 124, while, on the reverse surface of the product substrate 122, the micro lens array 130 is provided. Accordingly, there is no need to separately bond a micro lens array member to a polarization optical device with the use of adhesive agent or so. Thereby, in comparison to the related art, a positioning process and an assembly process are not required, and thus, the manufacturing costs can be reduced. Furthermore, there is no possibility of deformation otherwise occurring due to a difference in thermal expansion coefficients between the adhesive agent and the substrate.

One example of manufacturing the micro lens array 130 is next described.

For example, in the process described above with reference to FIG. 7D, after forming the protective layer 110, the reflection preventing film 113 is formed on the protective layer 110. Then, a photoresist is formed as a coat on the reverse surface of the product substrate 122, and a three-dimensional structure for the micro lens array 130 is formed in this photoresist. Then, by a method of anisotropic etching, the thus-produced surface structure in the photoresist is transferred to the reverse surface of the product substrate 122. Thus, the micro lens array 130 can be formed on the reverse surface of the product substrate 122.

After the resin 132 and the cover glass 134 are formed on the micro lens array 130, a dicing machine is used for cutting and separating the thus-obtained substrate into individual polarization optical devices. Thus, the polarization optical device in which, on the obverse surface of the product substrate 122, an array of the conductive elements 106 are provided via the undercoat layer 124, while, on the reverse surface of the product substrate 122, the micro lens array 130 is provided, can be obtained.

Although the example described with reference to FIG. 10 is an example in which the micro lens array 130 is provided on the reverse surface of the product substrate 122 in the embodiment described with reference to FIGS. 6A and 6B, a polarization optical device having a micro lens array on a reverse surface of a product substrate is not limited thereto. For example, it is also possible that a micro lens array is provided on a reverse surface of the product substrate 126 in the embodiment described above with reference to FIGS. 8A and 8B. Furthermore, it is also possible that the reflection preventing film 112 is omitted from the reverse surface of the product substrate 102 in the embodiment described above with reference to FIGS. 4A and 4B, and, instead, a micro lens array is provided on the reverse surface of the product substrate 102.

Thus, according to the second aspect of the present invention, since the protective layer is provided to protect the inorganic dielectric substrate (product substrate) including the array of strips of conductive elements, and the surface of the protective layer is flat, the heat resistance and the durability of the device are improved; also, since the surface of the protective layer is thus flat without unevenness, even when it is handled directly by hands and thus foreign matters adheres thereto, it can be easily removed, thus easy handling is provided.

Further, according to a manufacturing method therefor in the second aspect of the present invention, a fine structure (three-dimensional surface structure with high accuracy) including strips of conductive elements can be provided at high accuracy even in a mass production manner. Thereby, the production process can be simplified, repeatability can be improved, an easy manufacturing process can be achieved, and cost reduction can be achieved.

The sizes, shapes, materials, arrangements, manufacturing conditions and so forth described above with reference to the respective embodiments are merely examples, and the present invention is not limited thereto. That is, the present invention is not limited to the above-described embodiments, and variations and modifications may be made without departing from the basic concepts of the present invention.

The present application is based on Japanese Priority Applications Nos. 2003-058061 and 2003-178791, filed on Mar. 5, 2003 and Jun. 23, 2003, respectively, the entire contents of which are hereby incorporated by reference.

What is claimed is

1. A polarization optical device comprising:
an inorganic dielectric substrate transparent with respect to incident light having a flat surface; and
an array comprising a plurality of strips of conductive elements embedded in the flat surface of said inorganic dielectric substrate to an equal depth, with an equal width, and with an equal separation in a pitch shorter than the wavelength of the incident light in a manner such that the surfaces of said strips of conductive elements are flush with the surface of said substrate.

2. The polarization optical device as claimed in claim 1, wherein:
a reflection preventing film is formed on another surface of said substrate opposite to the surface in which said strips of conductive elements are embedded.

3. The polarization optical device as claimed in claim 1, wherein:
a conductive layer connected to the strips of conductive elements is also embedded in the surface of the substrate in a second zone other than a first zone in which said strips of conductive elements are formed.

4. A manufacturing method for a polarization optical device, comprising the steps of:
a) manufacturing a metal mold having a surface shape of fine structure comprising an array of projections arranged with an equal separation in a pitch shorter than the wavelength of incident light with an equal height and an equal width on a flat surface;
b) pressing a product substrate onto said metal mold via hardenable resin and transferring the surface shape of said metal mold to said resin on said product substrate;
c) hardening said resin;
d) removing said metal mold from said resin in a state in which said resin is bonded with said product substrate;
e) transferring the surface shape once transferred into said resin in said step b) to a surface of said product substrate according to a dry etching method; and
f) filling in depressions formed in said surface of said product substrate in said step e), with metal.

5. The manufacturing method as claimed in claim 4, wherein:
in said step b), before the product substrate is pressed onto the surface of the metal mold via the resin, mold releasing processing is performed on the surface of the metal mold.

6. The manufacturing method as claimed in claim 4, wherein:
said hardenable resin comprises ultraviolet curing resin.

7. The manufacturing method as claimed in claim 4, further comprising the steps of, in the stated order, for previously forming the fine structure on the surface of the metal mold in said step a):
g) coating with photosensitive material the surface of a host material for the metal mold in which said fine structure is to be formed;
h) writing a desired shape on said photosensitive material with an electron beam, developing and thus forming the desired shape in said photosensitive material; and
i) transferring said shape in said photosensitive material to said host material for the metal mold according to a dry etching method.

8. The manufacturing method as claimed in claim 7, wherein:
said host material for the metal mold comprises a material allowing a dry etching process to be performed thereon, and one selected from silicon material, semiconductor material, metal material, glass material, ceramic material, plastic material and hard rubber material.

9. The manufacturing method as claimed in claim 4, wherein:
in said step f), aluminum is used as the metal material for filling in the depressions, and a film is formed therewith according to an Al-CVD method.

10. The manufacturing method as calmed in claim 9, wherein:
said step f) performed according to the Al-CVD method comprises the steps of:
j) forming a seed layer comprising Ti or TiN material on the surface of the product substrate having the depressions; and
k) forming the Al-CVD film on said seed layer until said depressions are completely filled in therewith.

11. The manufacturing method as claimed in claim 4, wherein:
said steps e) and f) comprise the following steps of, in the stated order:
l) stopping the dry etching process in said step e) in a state in which the resin layer remains on the surface of the product substrate, and, in this state, forming a seed layer comprising Ti or TiN material on said surface of the product substrate having the depressions;
m) removing the resin layer remaining on the surface of the substrate together with the seed layer thus formed thereon; and
n) forming an Al-CVD film selectively so as to completely fill in the depressions having the seed layer remaining therein on the surface of the substrate.

12. The manufacturing method as claimed in claim 4, wherein:
said step f) comprises the following steps of:
o) heating to cause reflow process to form a film of said metal thicker than the depth of said depressions, then, heating the thus-formed metal layer in a vacuum chamber to such a temperature that the metal melts without exposing the metal layer to the air, so as to flatten the surface of said metal layer; and then,
p) removing the flattened metal layer until the surface of the product substrate is exposed.

13. The manufacturing method as claimed in claim 12, wherein:
said step p) is performed according to a CMP process or an etch back process.

14. A polarization optical device comprising:
an inorganic dielectric substrate transparent with respect to incident light and having a flat surface;
an array comprising a plurality of strips of conductive elements provided on the flat surface of said inorganic dielectric substrate with an equal height, with an equal width, and with an equal separation in a pitch shorter than the wavelength of the incident light; and
a protective layer, transparent with respect to the incident light and having a flat surface, provided on the surface of said inorganic dielectric substrate including said strips of conductive elements.

15. The polarization optical device as claimed in claim 14, further comprising:
an undercoat layer, adhesive with respect to the flat surface of said inorganic dielectric substrate and also to said strips of conductor elements, inserted therebetween.

16. The polarization optical device as claimed in claim 15, wherein:
said undercoat layer is formed on the entirety of said flat surface of the inorganic dielectric substrate, and also has a reflection preventing function.

17. The polarization optical device as claimed in claim 14, further comprising:
a reflection preventing layer provided on the surface of said protective layer on said inorganic dielectric substrate.

18. The polarization optical device as claimed in claim 14, further comprising:
a micro lens array formed on another surface of said inorganic dielectric substrate opposite to the surface on which said protective layer is formed.

19. The polarization optical device as claimed in claim 14, further comprising:
a reflection preventing layer formed on another surface of said inorganic dielectric substrate opposite to the surface on which said protective layer is formed.

20. The polarization optical device as claimed in claim 14, further comprising:
a conductive layer, formed on an undercoat layer, connected to the strips of conductive elements in a second zone other than a first zone in which said strips of conductive elements are formed.

21. A manufacturing method for a polarization optical device, comprising the steps of:
a) manufacturing a metal mold having a surface of fine shape comprising an array of depressions arranged with an equal separation in a pitch shorter than the wavelength of incident light with an equal depth and an equal width on a flat surface;
b) forming a metal layer on a surface of a product substrate;
c) pressing said metal layer of the product substrate onto said metal mold via a hardenable resin and transferring the surface shape of said metal mold to said resin on said metal layer;
d) hardening said resin;
e) removing said metal mold from said resin in a state in which said resin is bonded with said metal layer;
f) further transferring the surface shape once transferred to said resin in said step c) to a surface of said metal layer in a dry etching method so as to form an array of strips of conductive elements;
g) forming a protective layer on the product substrate including the strips of conductive elements; and
h) flattening a surface of said protective layer.

22. The manufacturing method as claimed in claim 21, said step b) comprising the steps of:
b-1) forming an undercoat layer, adhesive with respect to the product substrate and to the metal layer, on the surface of the product substrate; and then
b-2) forming said metal layer thereon.

23. The manufacturing method as claimed in claim 22, wherein:
said undercoat layer has a reflection preventing function.

24. The manufacturing method as claimed in claim 21, further comprising the step of:
i) forming a reflection preventing layer on the surface of said protective layer after said step h).

25. The manufacturing method as claimed in claim 21, further comprising the step of:
i) forming reflection preventing layers on the surface of said protective layer and on another surface of said product substrate opposite to the surface on which said protective layer is formed, after said step h).

26. The manufacturing method as claimed in claim 21, further comprising:
i) performing mold releasing processing on the surface of said metal mold before said product substrate is pressed onto said metal mold via the resin in said step c).

27. The manufacturing method as claimed in claim 21, wherein:
said hardenable resin comprises ultraviolet curing resin.

28. The manufacturing method as claimed in claim 21, wherein:
said fine shape on the surface of the metal mold is formed by the following steps of, in the stated order:
i) coating with a photosensitive layer the surface of a host material for the metal mold;
j) writing a desired shape on said photosensitive material with an electron beam, developing and thus forming the desired shape in said photosensitive material; and
k) transferring said shape formed in said photosensitive material in said step j) to said host material for the metal mold by a dry etching method.

29. The manufacturing method as claimed in claim 28, wherein:
said host material for the metal mold comprises a material allowing a dry etching process to be performed thereon, and one selected from silicon material, semiconductor material, metal material, glass material, ceramic material, plastic material and hard rubber material.

30. The manufacturing method as claimed in claim 21, wherein:
silicon dioxide is used as a material of said protective layer, and said protective layer is formed by a CVD method or a sputtering method.

31. The manufacturing method as claimed in claim 21, wherein:
a mixture of silicon dioxide and niobium oxide is used as a material of said protective layer, and said protective layer is formed by a CVD method or a sputtering method.

32. The manufacturing method as claimed in claim 30, wherein:
said protective layer is formed by the following steps of, in the stated order:
j) performing hydrogen processing or oxygen processing on the surface of the product substrate having the strips of conductive elements for improving adhesiveness;
k) forming the protective layer until zones left among the strips of conductive elements are completely filled in therewith; and
l) further forming the protective layer to a height greater than the height of the strips of conductive elements after completely filling in the zones left among the strips of conductive elements.

33. The manufacturing method as claimed in claim 31, wherein:
said protective layer is formed by the following steps of, in the stated order:
j) performing hydrogen processing or oxygen processing on the surface of the product substrate having the strips of conductive elements for improving adhesiveness;
k) forming the protective layer until zones left among the strips of conductive elements are completely filled in therewith; and
l) further forming the protective layer to a height greater than the height of the strips of conductive elements after completely filling in the zones left among the strips of conductive elements.

34. The manufacturing method as claimed in claim 21, further comprising the step of:
i) flattening the surface of said protective layer in a grinding process method or a CMP process method after said step h).
